(19) United States
(12) Patent Application Publication
(10) Pub. No.: US 2026/0277367 A1
(43) Pub. Date: Sep. 17, 2026

(54) DISPLAY MODULE, ELECTRONIC DEVICE INCLUDING THE SAME, AND METHOD FOR MANUFACTURING THE DISPLY MODULE

(71) Applicant: Samsung Display Co., Ltd., Yongin-si (KR)

(72) Inventors: KICHEOL SONG, Yongin-si (KR); Hyunchul KANG, Yongin-si (KR); YOUNJOENG GOH, Yongin-si (KR); GISUK KWON, Yongin-si (KR); YOUNGMOON KIM, Yongin-si (KR); JONG-HO SHIN, Yongin-si (KR); CHANG WOO LEE, Yongin-si (KR); JIHYE LIM, Yongin-si (KR); AHSELL CHO, Yongin-si (KR); YOUNGWOO CHOI, Yongin-si (KR); HWA-JEONG CHOI, Yongin-si (KR)

(21) Appl. No.: 19/547,240

(22) Filed: Feb. 23, 2026

(30) Foreign Application Priority Data
Mar. 13, 2025 (KR) 10-2025-0032661

(51) Int. Cl. G06F 3/044; H10K 59/12; H10K 59/40; H10K 59/80

(52) U.S. Cl. CPC G06F 3/044; H10K 59/1201; H10K 59/40; H10K 59/873; G06F 2203/04103

(57) ABSTRACT

A display module may include a display panel, wherein the display panel includes a display layer, which includes a light-emitting element, and an encapsulating layer on the display layer, an input sensor including a sensor conductive layer and a plurality of sensor insulating layers, a cover layer directly on an uppermost sensor insulating layer among the plurality of sensor insulating layers, wherein the cover layer includes an acrylate-based polymer, and a low-reflection member disposed on the cover layer.

### CROSS-REFERENCE TO RELATED APPLICATION

The present application claims priority to and the benefit of Korean Patent Application No. 10-2025-0032661, filed on Mar. 13, 2025, in the Korean Intellectual Property Office, the entire content of which is incorporated herein by reference.

### BACKGROUND

### 1. Field

One or more embodiments of the present disclosure relate to a display module, an electronic device including the display module, and a method for manufacturing the display module. For example, one or more embodiments of the present disclosure relate to a display module with improved or enhanced bonding strength between organic layers, an electronic device including the display module, and a method for manufacturing the display module.

### 2. Description of the Related Art

Multimedia electronic devices, such as televisions, mobile phones, tablet computers, navigation units, game consoles, and/or the like, display images to users via a display screen and provide touch-based input functionality that enables intuitive and convenient user interaction. The electronic devices may include a display panel that generates images and an input sensor that senses (detects) a user's touch.

The electronic devices may include two or more stacked structures. However, the reliability of these electronic device may be compromised if (e.g., when) the bonding strength between adjacent stacked structures is insufficient.

### SUMMARY

One or more aspects of embodiments of the present disclosure are directed toward a display module which has an improved or enhanced impact resistance and reliability, including a cover layer having excellent or suitable bonding strength to an uppermost sensor insulating layer of an input sensor, and an electronic device including the display module.

One or more aspects of embodiments of the present disclosure are directed toward a method for manufacturing a display module including a cover layer having excellent or suitable bonding strength to an uppermost sensor insulating layer of an input sensor.

Additional aspects of embodiments will be set forth in part in the description which follows and, in part, will be apparent from the description or may be learned by practice of the presented embodiments of the disclosure.

In one or more embodiments of the present disclosure, a display module includes: a display panel including a display layer, which includes a light-emitting element, and an encapsulation layer arranged on the display layer; an input sensor arranged on the display panel, the input sensor including a sensor conductive (e.g., electrically conductive) layer and a plurality of sensor insulating layers, wherein the plurality of sensor insulating layers includes an uppermost sensor insulating layer; a cover layer arranged directly on the uppermost sensor insulating layer of the plurality of sensor insulating layers; and a low-reflection member arranged on the cover layer; wherein the cover layer includes an acrylate-based polymer; and at least one polymer derived from a silane coupling agent, an epoxy-based compound, or an aromatic monomer, or includes an epoxy acrylate-based polymer.

In one or more embodiments, the uppermost sensor insulating layer may include an epoxy-based polymer.

In one or more embodiments, the sensor conductive layer may include a first sensor conductive layer and a second sensor conductive layer arranged on the first sensor conductive layer, and the plurality of sensor insulating layers may include a first sensor insulating layer arranged below the first sensor conductive layers, a second sensor insulating layer arranged above the first sensor conductive materials, and a third sensor insulating layer that is the uppermost sensor insulating layer.

In one or more embodiments, the first sensor insulating layer and the second sensor insulating layer may include at least one of silicon nitride (e.g., SiₓN_{y}, wherein 0<x≤3 and 0<y≤4; e.g., Si₃N₄) or silicon oxynitride (e.g., SiₓON_{y}, wherein 0<x≤2 and 0≤y≤2; e.g., SiON or Si₂N₂O), respectively.

In one or more embodiments, the cover layer may be formed or arranged by providing an acrylate-based composition on the input sensor by an inkjet printing method and ultraviolet curing the provided acrylate-based composition.

In one or more embodiments, the input sensor may be arranged directly on the encapsulation layer.

In one or more embodiments, the cover layer may be arranged directly on the entire upper surface of the uppermost sensor insulating layer.

In one or more embodiments, the low-reflection member may include a polarizing plate and an interlayer adhesive layer arranged directly between the cover layer and the polarizing plate.

In one or more embodiments, the display module may be divided into an active region in which the light-emitting element is arranged, and a peripheral region in which the light-emitting element is not arranged and located or arranged outside the active region, and wherein edge lines of the uppermost sensor insulating layer, the cover layer, and the low-reflection member may overlap each other in the peripheral region.

In one or more embodiments of the present disclosure, a method for manufacturing a display module includes: providing a display panel including a display layer, which includes a light-emitting element, and an encapsulation layer arranged on the display layer; forming an input sensor, including a sensor conductive (e.g., electrically conductive) layer and a plurality of sensor insulating layers, on the display panel; providing an acrylate-based composition on an uppermost sensor insulating layer of the plurality of sensor insulating layers by an inkjet printing method; forming a cover layer by ultraviolet-curing the acrylate-based composition; providing a low-reflection member on the cover layer; and laser-cutting one sides of the display panel, the input sensor, the cover layer, and the low-reflection member so that (e.g., such that) their cross-sectional profiles are aligned (e.g., such that the cross-section view or cross-sectional profiles of the display panel, the input sensor, the cover layer, and the low-reflection member are aligned).

In one or more embodiments, the acrylate-based composition may include an acrylate-based monomer; and at least one of a silane coupling agent, an epoxy-based monomer, or an aromatic monomer.

In one or more embodiments, the acrylate-based composition may further include an epoxy acrylate-based monomer.

In one or more embodiments, the uppermost sensor insulating layer may be formed from (or made from) an epoxy-based compound.

In one or more embodiments, the forming of the cover layer may include ultraviolet-curing in a N₂ atmosphere supplied with N₂ so that (e.g., such that) the O₂ content (e.g., amount) is about 10% or less.

In one or more embodiments, the degree of curing of the acrylate-based composition throughout the cover layer may be about 95% or more.

In one or more embodiments of the present disclosure, an electronic device includes: a display module including a display panel and an input sensor arranged on the display panel; and a power module that supplies power to the display module, wherein the display module includes: a display panel including a display layer, which includes a light-emitting element, and an encapsulation layer arranged on the display layer; an input sensor arranged on the display panel and including a sensor conductive (e.g., electrically conductive) layer and a plurality of sensor insulating layers; a cover layer arranged directly on an uppermost sensor insulating layer of the plurality of sensor insulating layers; and a low-reflection member arranged on the cover layer; wherein the cover layer includes an acrylate-based polymer and at least one polymer derived from a silane coupling agent, an epoxy-based compound, or an aromatic monomer, or an epoxy acrylate-based polymer.

In one or more embodiments, the uppermost sensor insulating layer may include an epoxy-based polymer.

In one or more embodiments, the input sensor may be arranged directly on the encapsulation layer, and the low-reflection member may be directly arranged on the cover layer.

In one or more embodiments, the electronic device may further include at least one of a processor or a memory.

In one or more embodiments, the electronic device may be an image display device, a wearable device, or a vehicle device.

For example, the display module, the manufacturing method, and the electronic device as described in the present disclosure provide a synergistic integration of structural and material features that enhance the performance and reliability of the display module. For example, the utilization of a cover layer including an acrylate-based polymer and at least one of a silane coupling agent, an epoxy compound, or a polymer derived from an aromatic monomer- or alternatively, an epoxy acrylate-based polymer-directly on the uppermost sensor insulating layer improves bonding strength between the cover layer and the input sensor. This enhanced bonding strength contributes to improved or enhanced impact resistance, environmental durability, and optical performance of the display module. The method of forming the cover layer via inkjet printing and ultraviolet curing further enables precise layer formation and material control, which supports consistent manufacturing quality. Also, the alignment of cross-sectional profiles through laser cutting facilitates compact integration of the display module into electronic devices. These effects/aspects are beneficial in portable, wearable, and automotive applications, where mechanical robustness and display clarity are desired. Accordingly, the structural and process features recited in the claims are directed toward achieving these technical effects/aspects.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a block diagram of an electronic device according to one or more embodiments;

FIG. 2 is a schematic view of each of electronic devices according to one or more embodiments;

FIG. 3 is a perspective view of an electronic device according to one or more embodiments;

FIG. 4 is an exploded perspective view of an electronic device according to one or more embodiments;

FIG. 5 is a cross-sectional view of an electronic device of one or more embodiments;

FIG. 6 is a cross-sectional view of a portion of a display module according to one or more embodiments;

FIG. 7 is a cross-sectional view of a portion of a display module according to one or more embodiments;

FIG. 8 is a flowchart of a method for manufacturing a display module according to one or more embodiments;

FIG. 9 is a diagram illustrating one or more of the steps (e.g., acts or tasks) of the method for manufacturing a display module according to one or more embodiments; and

FIGS. 10A and 10B are diagrams showing evaluation results of the thermal stability of the cover layer.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As used herein, “combination thereof” may refer to a mixture, a stack, a composite, a copolymer, an alloy, a blend, a reaction product, and/or the like of constituents.

In the present disclosure, it will be understood that if (e.g., when) an element (or a region, a layer, a portion, and/or the like) is referred to as being “on,” “connected to,” or “coupled to” another element, it may be directly on, directly connected to, or directly coupled to the other element, or other elements may be present therebetween. In contrast, if (e.g., when) an element is referred to as being “directly on,” “directly connected to,” or “directly coupled to” another element, there are no intervening elements present therebetween.

In the drawings, the thickness, ratio, and size of the elements may be exaggerated for effectively describing the technical contents.

It will be understood that, although the terms “first,” “second,” and/or the like may be used herein to describe one or more suitable elements, the elements are not to be limited by these terms. These terms are only used to distinguish one element, component, region, layer, or section from another element, component, region, layer, or section. For instance, a first element, a first component, a first region, a first layer, or a first section discussed may be termed a second element, a second component, a second region, a second layer, or a second section without departing from the scope of the present disclosure. Similarly, a second element, a second component, a second region, a second layer, or a second section may be termed a first element, a first component, a first region, a first layer, or a first section.

The terms “below,” “under,” “on the lower side,” “above,” “over,” “on the upper side,” and/or the like may be used to describe the relationships between the elements illustrated in the drawings. These terms are relative concepts and are described on the basis of the directions indicated in the drawings.

It will be further understood that the terms “includes,” “including,” “has,” and/or “having,” if (e.g., when) used in the present disclosure, specify the presence of stated features, numbers, steps (e.g., acts or tasks), operations, elements, components, or combinations thereof, but do not preclude the possibility of the presence or addition of one or more other features, numbers, steps (e.g., acts or tasks), operations, elements, components, and/or combinations thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Unless otherwise defined, all terms (including technical and scientific terms) used herein have substantially the same meaning as generally understood by one of ordinary skill in the art to which the present disclosure belongs. It will be further understood that terms, such as those defined in generally used dictionaries, should be interpreted as having a meaning that is consistent with their meaning in the context of the relevant art and will not be interpreted in an idealized or overly formal sense unless expressly so defined herein.

Hereinafter, a display module of one or more embodiments, an electronic device of one or more embodiments, and a display module manufacturing method of one or more embodiments will be described in more detail with reference to the accompanying drawings.

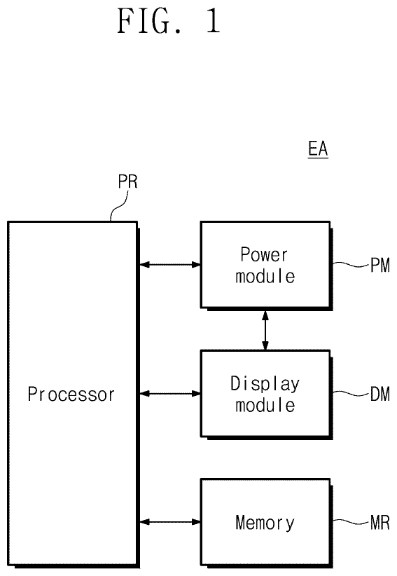

FIG. 1 is a block diagram of an electronic device according to one or more embodiments. Referring to FIG. 1, an electronic device EA according to one or more embodiments may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), or a controller.

The memory MR may be to store data information necessary or desirable for the operation of the processor PR or the display module DM. If (e.g., when) the processor PR executes an application stored in the memory MR, an image data signal and/or an input control signals may be transmitted to the display module DM, and the display module DM may be to process the transmitted signals to output image information through a display screen. The display module DM may include a display panel which displays an image.

The power module PM may include a power supply module, such as a power adapter or a battery device, and a power conversion module which converts a power supplied from the power supply module to generate a power desirable or required for an operation of the electronic device EA.

At least one selected from among the respective components of the electronic device EA as described in one or more embodiments may be included in a display device including a display module according to one or more embodiments as described in more detail herein. In one or more embodiments, one or more of the individual modules that are functionally included in one module may be included in the display device, and others may be provided separately from the display device. For example, the display device may include a display module DM, and the processor PR, the memory MR, and the power module PM may be provided in a form of other device in the electronic device EA other than the display device.

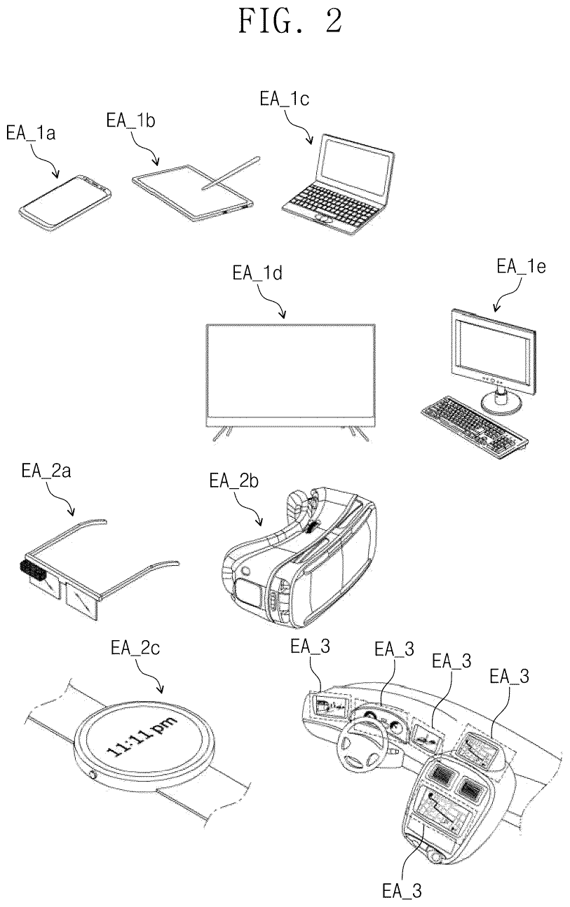

FIG. 2 is a schematic view of an electronic devices according to one or more embodiments.

Referring to FIG. 2, one or more suitable electronic devices, including a display device according to one or more embodiments, may include an electronic device for image display, such as a smart phone EA_1a, a tablet computer EA_1b, a laptop computer EA_1c, a television EA_1d, and a desktop monitor EA_1e, and a wearable electronic device, such as smart glasses EA_2a, a head mounted display EA_2b, and a smart watch EA_2c, as well as a vehicle electronic device EA_3, such as a center information display (CID)) arranged on an instrument panel, a center fascia, and a dashboard of a vehicle, and a room mirror display.

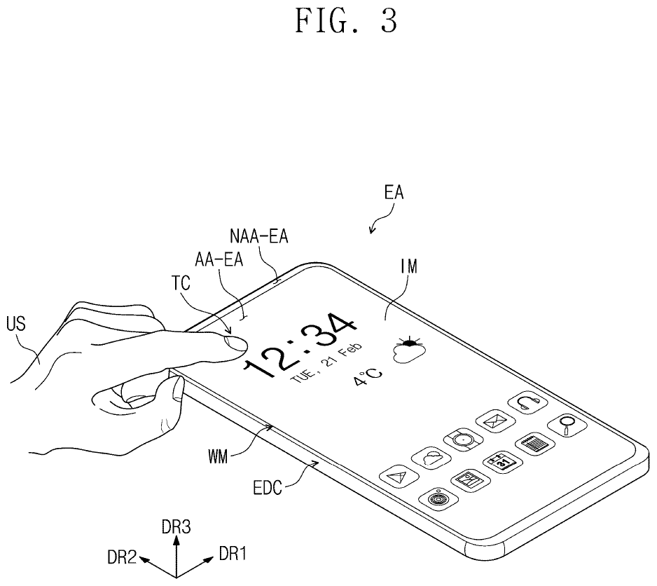

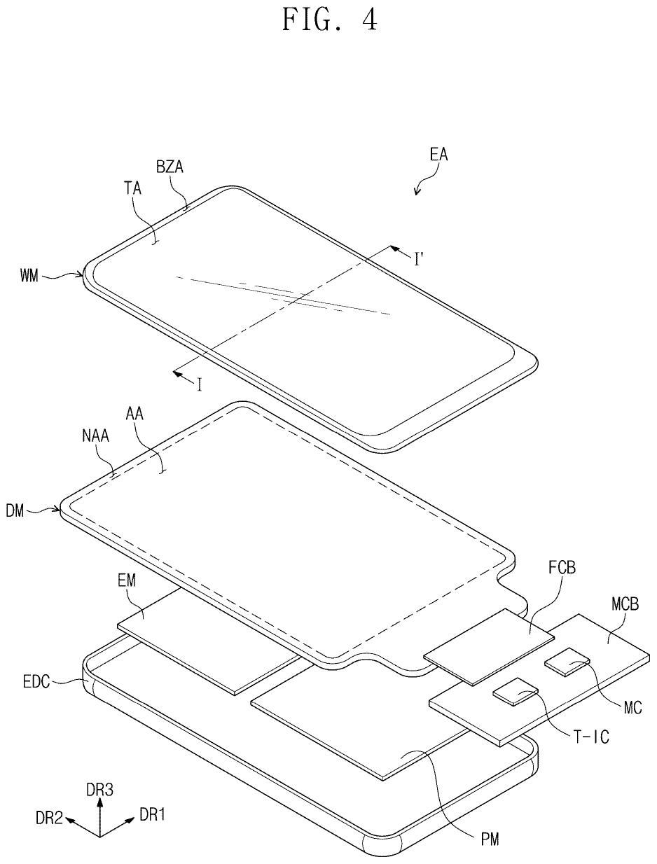

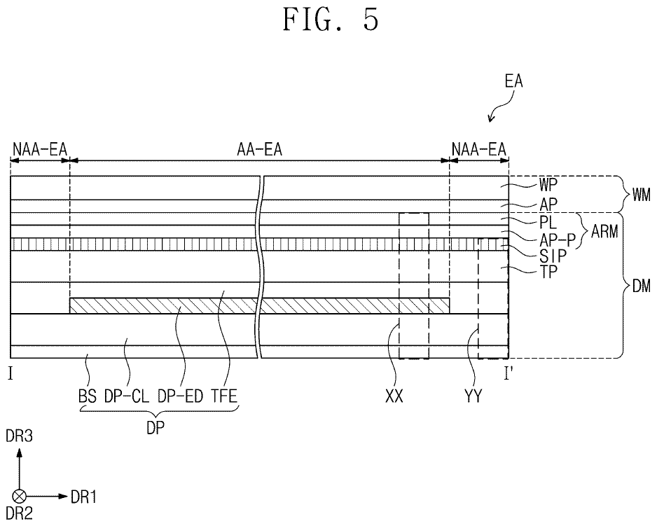

FIG. 3 is a perspective view illustrating an electronic device according to one or more embodiments. FIG. 4 is an exploded perspective view of an electronic device of one or more embodiments, and FIG. 5 is a cross-sectional view of the electronic device. FIG. 5 is a cross-sectional view corresponding to the line I-I′ of FIG. 4.

FIG. 3 illustrates a smart phone as an example of the electronic device EA. However, the description of the electronic device EA as described with reference to FIG. 3 and/or the like may be equally applied to other electronic devices.

The electronic device EA may be rigid or flexible. The term “flexible” refers to having a bendable property. For example, a flexible electronic device EA may include a curved device, a rollable device, or a foldable device.

FIG. 3 and the following drawings illustrate a first directional axis DR1 to a third directional axis DR3, and directions indicated by the first to third directional axes DR1, DR2, and DR3 as described in the present disclosure may be converted to other directions as a relative concept. The directions indicated by the first to third direction axes DR1, DR2, and DR3 may be referred to as the first to third directions DR1, DR2, DR3, and the same reference numerals may be used. In the present disclosure, the first directional axis DR1 and the second directional axis DR2 may be orthogonal to each other, and the third directional axis DR3 may be a direction normal to a plane defined by the first directional axes DR1 and DR2.

The thickness direction of the electronic device EA may be a direction substantially parallel to the third directional axis DR3, which is a direction normal to a plane defined by the first directional axis DR1 and the second directional axis DR2. In the present disclosure, a front surface (or an upper surface) and a rear surface (or a lower surface) of the members constituting the electronic device EA may be defined with reference to the third directional axis DR3. The front surface (or the upper surface) and the rear surface (or the lower surface) of the respective members constituting the electronic device EA may be opposed to each other in the third direction DR3, and the normal direction of each of the front surface and the rear surface may be substantially parallel to the third direction DR3. A separation distance between the front surface and the rear surface defined along the third direction DR3 may correspond to the thickness of the member.

In the present disclosure, the wording “on a plane” or “plan view” may be defined as a state viewed in the third direction DR3. In the present disclosure, the wording “on a cross-section” or “cross-section view” may be defined as a state viewed in the first direction DR1 or the second direction DR2. In one or more embodiments, directions indicated by the first to third directions DR1, DR2, and DR3 may be converted to other directions as a relative concept.

The electronic device EA according to one or more embodiments may be to display an image IM through an active region AA-EA. The active region AA-EA may include a plane defined by the first direction DR1 and the second direction DR2. The active region AA-EA may further include a curved surface bent from at least one side of a plane defined by the first direction DR1 and the second direction DR2. A surface on which the image IM is displayed may correspond to a front surface of the electronic device EA. The image IM may include a still image as well as a dynamic image.

A peripheral region NAA-EA may be adjacent to the active region AA-EA. The peripheral region NAA-EA may be around (e.g., surround) the active region AA-EA. Accordingly, the shape of the active region AA-EA may be substantially defined by the peripheral region NAA-EA. However, this is illustrated as an example, and the peripheral region NAA-EA may be arranged adjacent to only one side of the active region AA-EA or may not be provided. The electronic device EA according to one or more embodiments of the present disclosure may include active regions of one or more suitable shapes, and is not limited to any one or more embodiments.

On a plane (e.g., in plan view), the electronic device EA may have a rectangular shape (e.g., a substantially rectangular shape) with short sides extending in a first direction DR1 on a plane and long sides extending in a second direction DR2 crossing (e.g., intersecting) the first direction DR1. However, without being limited thereto, the electronic device EA may have one or more suitable shapes, such as a circular shape (e.g., a substantially circular shape) and/or a polygonal shape (e.g., a substantially polygonal shape) on a plane (e.g., in plan view).

The electronic device EA may be to sense an external input TC applied from the outside. The external input TC may include one or more suitable types (kinds) of inputs, such as force, pressure, temperature, and/or light. In one or more embodiments, the external input TC may be a touch input by a hand of the user US applied to the front surface of the electronic device EA. However, this is an example, and the external input TC may include all inputs that may change the capacitance of the input sensor. The area of the electronic device EA which senses the external input TC is not limited to the front surface of the electronic device EA, and depending on the structure of the electronic device, the electronic device EA may be to sense the external input TC of the user US applied to the side surface or the rear surface.

Referring to FIGS. 3 to 5, an electronic device EA according to one or more embodiments may include a display module DM. The display module DM may be configured or arranged to generate an image and sense an externally applied input. The display module DM according to one or more embodiments may include a display panel DP, an input sensor TP arranged on the display panel DP, and a cover layer SIP arranged on the input sensor TP. In one or more embodiments, the display module DM of one or more embodiments may further include a low-reflection member ARM arranged on the input sensor TP. In the display module DM of one or more embodiments, the cover layer SIP may be directly arranged between the input sensor TP and the low-reflection member ARM. In one or more embodiments, the cover layer SIP may be to function as a flat (e.g., substantially flat) layer arranged on the input sensor TP to serve as a base surface on which the low-reflection member ARM and/or the like is arranged.

The cover layer SIP according to one or more embodiments may be an organic layer having excellent or suitable bonding characteristics with respect to the upper surface of the input sensor TP. The cover layer SIP may have improved or enhanced impact resistance by having low modulus characteristics while having excellent or suitable bonding strength to the input sensor TP. Accordingly, the display module DM according to one or more embodiments may exhibit improved or enhanced reliability and impact resistance resulting from superior or suitable bonding characteristics between the cover layer SIP and the input sensor TP.

In one or more embodiments, the cover layer SIP may be formed to have a high degree of curing to exhibit excellent or suitable thermal stability. Accordingly, damage to the cover layer SIP by the laser may be minimized or reduced in a laser cutting process and/or the like used in manufacturing the display module DM, and thermal stability against heat generated during laser cutting may also be increased, so that (e.g., such that) a problem, such as peeling from an adjacent layer after laser cutting, may be minimized or reduced.

The electronic device EA according to one or more embodiments may include a window module WM arranged above the display module DM. The electronic device EA according to one or more embodiments may further include an electronic module EM, a power module PM, and a housing EDC. In one or more embodiments, the electronic device EA according to one or more embodiments may further include at least one of a processor PR (see FIG. 1) or a memory MR (see FIG. 1), in addition to the display module DM and the power module PM that supplies power to the display module DM.

An active region AA and a peripheral region NAA may be defined in the display module DM according to one or more embodiments. The active region AA may be an area activated according to an electrical signal. The peripheral region NAA may be an area adjacent to at least one side of the active region AA.

The active region AA may correspond to the active region AA-EA of the electronic device as illustrated in FIG. 3. The peripheral region NAA may be around (e.g., surround) the active region AA. However, embodiments of the present disclosure are not limited thereto, and one or more of the peripheral regions NAA may not be provided in one or more embodiments, unlike that illustrated in FIG. 4 and/or the like. The peripheral region NAA may correspond to the peripheral region NAA-EA of the electronic device as illustrated in FIG. 3.

The display module DM according to one or more embodiments may include a peripheral region NAA arranged on at least one side of the active region AA, and a portion of the peripheral region NAA may be provided with a driving circuit or a driving wiring to operate the active region AA.

The window module WM may be arranged on the display module DM to protect the display module DM from external impacts or scratches. The window module WM may cover the entire outer surface of the display module DM. The front surface of the window module WM may correspond to the upper surface of the electronic device EA described above.

In one or more embodiments, the window module WM may include a base substrate WP that is an optically transparent (e.g., substantially transparent) insulating (e.g., electrically insulating) material. The base substrate WP may include an optically clear (e.g., substantially clear or substantially transparent) insulating (e.g., electrically insulating) material. The base substrate WP may include at least one selected from a glass substrate and a synthetic resin film. The base substrate WP may have a single-layer structure or a multilayer structure in which a plurality of films are bonded. The window module WM may further include a functional layer, such as an anti-fingerprint layer, a phase control layer, or a hard coat layer arranged on the base substrate WP.

The window module WM may further include an adhesive layer AP. The base substrate WP and the display module DM may be coupled to each other through the adhesive layer AP. However, without being limited thereto, the adhesive layer AP may not be provided, and the base substrate WP of the window module WM may be directly arranged on the display module DM.

The window module WM may be divided into a transmissive portion TA and a bezel portion BZA. The transmissive portion TA may be a portion corresponding to the active region AA of the display module DM, and the bezel portion BZA may be a portion corresponding to the peripheral region NAA of the display module DM. The bezel portion BZA may define a shape of the transmissive portion TA. The bezel portion BZA may be adjacent to the transmissive portion TA and may be around (e.g., surround) the transmissive portion TA. However, embodiments of the present disclosure are not limited to that shown, and the bezel portion BZA may be arranged adjacent to only one side of the transmissive portion TA, or a part of the bezel portion BZA may not be provided. The bezel portion BZA of the window module WM may have a lower light transmittance than the transmissive portion TA.

The display module DM may include a main circuit board MCB and a flexible circuit film FCB which electrically connects the main circuit board MCB and the display module DM. In one or more embodiments, the main circuit board MCB may be electrically connected to the electronic module EM through a connector.

A sensor control circuit T-IC and a main controller MC may be arranged on the main circuit board MCB. The main controller MC may be to control the overall operation of the electronic device EA. For example, the main controller MC may be to control operations of the display panel DP and the input sensor TP. In one or more embodiments, the main controller MC may be to control the operation of the electronic module EM. The main controller MC may include at least one microprocessor.

The flexible circuit film FCB may be connected to each of the display panel DP and the input sensor TP and may electrically connect the display panel DP and the input sensor TC to the main circuit board MCB. The input sensor TP may be electrically connected to the display panel DP and electrically connected to the main circuit board MCB through the flexible circuit film FCB. However, embodiments of the present disclosure are not limited thereto, and the input sensor TP may be electrically connected to the main circuit board MCB through an additional flexible circuit film, or the flexible circuit film FCB may not be provided and the main circuit board MCB may be directly connected on the display panel DP.

The electronic module EM may include one or more suitable functional modules necessary or desirable to drive the electronic device EA. For example, the electronic module EM may include a wireless communication module, an image input module, a sound input module, a sound output module, a memory, an external interface module, and and/or the like. The modules of the electronic module EM as described in one or more embodiments may be mounted on the main circuit board MCB or may be electrically connected to the main circuit board MCB via an additional flexible circuit board.

The power module PM may be electrically connected to the electronic module EM. The power module PM may be to supply power desirable or required for the overall operation of the electronic device EA. For example, the power module PM may include a battery device that is generally available.

The window module WM and the housing EDC may be coupled to each other to constitute the exteriors of the electronic device EA. The window module WM and the housing EDC may be coupled to form an inner space in which components of the electronic device EA are accommodated. The display module DM, the flexible circuit film FCB, the main circuit board MCB, the electronic module EM, the power module PM, and/or the like may be accommodated in the inner space as described in one or more embodiments. A portion of the display module DM may be accommodated in the housing EDC by bending the flexible circuit film FCB and the main circuit board MCB to be opposite to (e.g., face) the rear surface of the display module DM.

The housing EDC may include a relatively high rigid material. For example, the housing EDC may include a frame and/or a plate that contains glass, plastic, or metal, or a combination thereof. The housing EDC may be to absorb an impact applied from the outside, or prevent or reduce infiltration of foreign substances/moisture and/or the like from the outside, thereby protecting the display module DM and/or the like accommodated in the housing EDC.

In the electronic device EA according to one or more embodiments, the display panel DP may be configured or arranged to generate an image. The display panel DP may be a light-emitting display panel, for example, the display panel DP may be an organic light-emitting display panel, an inorganic light-emitting display panel, a quantum dot display panel, a micro LED display panel, or a nano LED display panel. The display panel DP may be referred to as a display layer.

Referring to FIG. 5, the display panel DP may include a base layer BS, a circuit layer DP-CL, a display layer DP-ED, and an encapsulation layer TFE.

The base layer BS may be a member that provides a base surface on which the circuit layer DP-CL is arranged. The base layer BS may be a rigid substrate or a flexible substrate capable of bending, folding, rolling, and/or the like. The base layer BS may be a glass substrate, a metal substrate, a polymer substrate, and/or the like. However, embodiments of the present disclosure are not limited thereto, and the base layer BS may be an inorganic layer, an organic layer, or a composite material layer.

The base layer BS may have a multi-layered structure. For example, the base layer BS may include a first synthetic resin layer, an intermediate layer having a multi-layered structure or a single-layered structure, and a second synthetic resin layer arranged on the intermediate layer. The intermediate layer may be referred to as a base barrier layer. The intermediate layer may include, but is not particularly limited to, a silicon oxide (e.g., SiOₓ, wherein 0<x≤2; e.g., SiO₂) layer and an amorphous (e.g., non-crystalline) silicon (a-Si) layer arranged over the silicon oxide layer. For example, the intermediate layer may include at least one of a silicon oxide layer, a silicon nitride layer, a silicon oxynitride layer, or an amorphous (e.g., non-crystalline) silicon layer.

Each of the first and second synthetic resin layers may include a polyimide-based resin. Each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the present disclosure, the “~~”-based resin refers to containing a functional group of “~~”.

The circuit layer DP-CL may be arranged on the base layer BS. The circuit layer DP-CL may include an insulating (e.g., electrically insulating) layer, a semiconductor pattern, a conductive (e.g., electrically conductive) pattern, and a signal wiring. An insulating (e.g., electrically insulating) layer (e.g., a layer that is an insulator), a semiconductor layer, and a conductive (e.g., electrically conductive) layer (e.g., a layer that is a conductor) may be formed on the base layer BS by coating, vapor deposition, and/or the like, and then the insulating layer, the semiconductor layer, and the conductive layer may be selectively patterned through a plurality of photolithography processes. Thereafter, the semiconductor pattern, the conductive pattern, and the signal wiring included in the circuit layer DP-CL may be formed. The circuit layer DP-CL may include a plurality of inorganic insulating (e.g., electrically insulating) layers and a plurality of organic insulating (e.g., electrically insulating) layers as insulating (e.g., electrically insulating) layers.

The display layer DP-ED may be arranged on the circuit layer DP-CL. The display layer DP-ED may include a light-emitting element. For example, the display layer DP-ED may include an organic light emitting material, an inorganic light emitting material, an organic-inorganic light emitting material, quantum dots, quantum rods, micro LEDs, or nano LEDs. The light-emitting elements of the display layer DP-ED may be electrically connected to the driving elements of the circuit layer DP-CL and may be configured or arranged to generate light in response to signals provided by the driving elements to display an image.

The encapsulation layer TFE may be arranged on the display layer DP-ED. The encapsulation layer TFE may be to protect the display layer DP-ED from foreign substances, such as moisture, oxygen, and/or dust particles. The encapsulation layer TFE may seal the light-emitting elements of the display layer DP-ED. The encapsulation layer TFE may include at least one thin film to improve or enhance the optical efficiency of the display layer DP-ED or to protect the display layer DP-ED.

The input sensor TP may be arranged on the display panel DP. The input sensor TP may be to sense an external input TC applied from the outside. The external input TC may be an input of the user US. The input of the user US may include one or more suitable types (kinds) of external inputs, such as part of the user's body, light, heat, pen, and/or pressure. The input sensor TP may be to sense the external input TC and provide an input signal including information on the external input TC so that (e.g., such that) the display panel DP may generate the image IM corresponding to the external input TC. The input sensor TP may be driven in one or more suitable manners, such as, but not limited to, a capacitive manner, a resistive manner, an infrared manner, a sound wave manner, or a pressure manner. In one or more embodiments, the input sensor TP may be described as being driven in a capacitive manner.

The input sensor TP may be formed on the display panel DP through a substantially continuous process. In this case, it may be expressed that the input sensor TP may be directly arranged on the display panel DP. The wording “directly arranged” may refer to that a third component is not arranged between the input sensor TP and the display panel DP. For example, an additional adhesive member may not be arranged between the input sensor TP and the display panel DP.

The low-reflection member ARM may be arranged on the input sensor TP. The low-reflection member ARM may be a reflection reduction layer which reduces reflectance by external light incident from the outside of the display module DM. The low-reflection member ARM may be formed on the input sensor TP through a substantially continuous process. For example, the low-reflection member ARM may include a polarizing film including a phase retarder and/or a polarizer, a multilayer reflective layer that offsets reflected light through destructive interference, or a color filter arranged corresponding to a pixel array and a light-emitting color of the display panel DP.

In one or more embodiments, the low-reflection member ARM may include a polarizing plate PL including a polarizer. The low-reflection member ARM may include a polarizing plate PL and an interlayer adhesive layer AP-P arranged under the polarizing plate PL. The polarizing plate PL and the cover layer SIP may be bonded to each other by the interlayer adhesive layer AP-P. In one or more embodiments, the interlayer adhesive layer AP-P may not be provided.

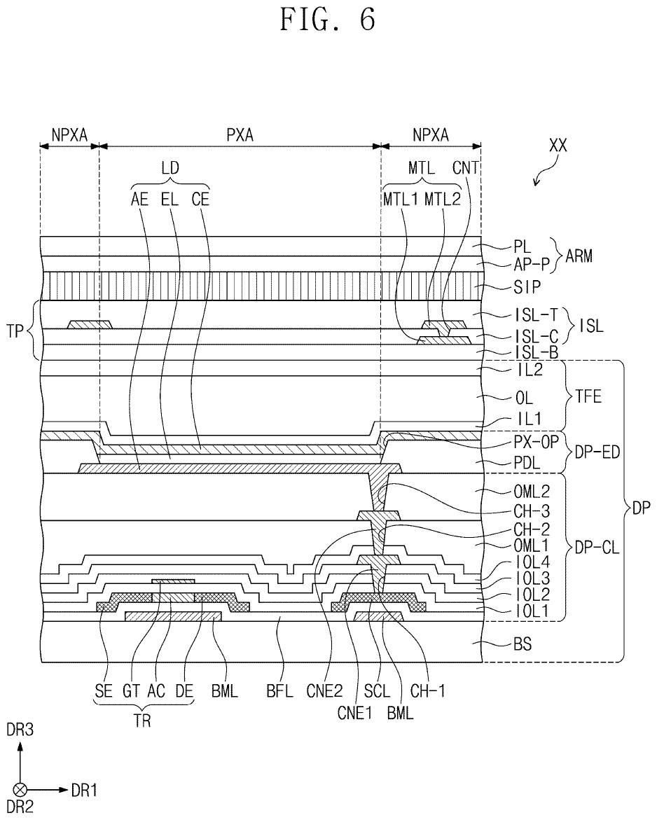

FIG. 6 is a cross-sectional view of a portion of an electronic device according to one or more embodiments. FIG. 6 is a cross-sectional view of a portion corresponding to the XX region of FIG. 5. FIG. 6 exemplarily illustrates a portion including one pixel. Any one of pixels may include an equivalent circuit including a plurality of transistors, at least one capacitor, and a light-emitting element. The configuration or arrangement of an equivalent circuit of a pixel may be modified in one or more suitable forms, and, in FIG. 6, one transistor TR and one light-emitting element LD included in one pixel are exemplarily illustrated.

The display panel DP according to one or more embodiments may include a plurality of insulating (e.g., electrically insulating) layers, a transistor, a conductive (e.g., electrically conductive) pattern, and a signal wiring. A plurality of inorganic films, a plurality of organic films, a semiconductor layer, and a conductive (e.g., electrically conductive) layer may be formed by coating and/or vapor deposition. Thereafter, inorganic films, organic films, the semiconductor layer, and the conductive layer may be selectively patterned in a manner of photolithography. In this manner, a circuit layer DP-CL may include the plurality of insulating layers respectively formed from (or composed of) inorganic films and organic films, the transistor including the semiconductor pattern formed from (or composed of) the semiconductor layer, the conductive pattern formed from (or composed of) the conductive layer, and the signal wiring.

Then, a display layer DP-ED including the light-emitting element LD may be formed on the circuit layer DP-CL, and the encapsulation layer TFE covering the display layer DP-ED may be formed.

Referring to FIG. 6, the circuit layer DP-CL may include a shielding electrode BML, a buffer layer BFL, a plurality of insulating layers IOL1, IOL2, IOL3, and IOL4 including an inorganic film, a plurality of insulation layers OML1 and OML2 including an organic film, a transistor TR, connection electrodes CNE1 and CNE2, and a signal line SCL.

The shielding electrode BML may be arranged on the base layer BS. The shielding electrode BML may overlap the transistor TR. In one or more embodiments, the shielding electrode BML may be arranged under the signal line SCL. The shielding electrode BML may be to block light incident on the transistor TR or the signal line SCL from the lower side of the display panel DP, thereby protecting the semiconductor patterns or the conductive patterns, such as the transistor TR and the signal line SCL. In one or more embodiments, the shielding electrode BML may not be provided.

The buffer layer BFL may be arranged on the base layer BS to cover the shielding electrode BML. The buffer layer BFL may improve or enhance a coupling force between the semiconductor patterns or the conductive patterns arranged on the buffer layer BFL and the base layer BS. In one or more embodiments, the buffer layer BFL may prevent or reduce diffusion of metal atoms and/or impurities from the base layer BS into the semiconductor patterns or the conductive patterns.

The buffer layer BFL may be an inorganic film. The buffer layer BFL may include at least one of silicon oxide, silicon nitride, or silicone oxynitride. For example, the buffer layer BFL may include a structure in which a silicon oxide layer and a silicon nitride layer are alternately stacked.

The transistor TR may include a source SE, a channel AC, a drain DE, and a gate GT. The source SE, the channel AC, and the drain DE of the transistor TR may be formed from a semiconductor pattern. The source SE and the drain DE may extend in opposite directions from the channel AC on a cross-section. FIG. 6 illustrates a portion of the signal line SCL formed from the semiconductor pattern. In one or more embodiments, the signal line SCL may be connected to the drain DE of the transistor TR on a plane.

The semiconductor pattern of the transistor TR may include polysilicon, amorphous (e.g., non-crystalline) silicon, and/or a metal oxide, and is not limited to any one as long as it has semiconductor properties.

The semiconductor pattern may include a plurality of regions that are demarcated according to the magnitude of conductivity (e.g., electrical conductivity). Regions doped with a dopant or in which metal oxides are reduced with a metal oxide of the semiconductor pattern may exhibit high conductivity (e.g., electrical conductivity) and may be to substantially serve as a source electrode and a drain electrode of the transistor TR. The highly conductive regions in the semiconductor pattern may correspond to the source SE and the drain DE of the transistor TR. Regions which are undoped or doped at a low concentration or in which the metal oxide is unreduced and thus the conductivity is low may correspond to the channel AC (or active) of the transistor TR.

The first insulating layer IOL1 may cover the semiconductor pattern of the transistor TR and may be arranged on the buffer layer BFL. The gate GT of the transistor TR may be arranged on the first insulating layer IOL1. The gate GT may overlap the channel AC of the transistor TR. In one or more embodiments, the gate GT may be to function as a mask in a process of doping a semiconductor pattern of the transistor TR.

The gate GT may include, but is not particularly limited to, titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), and/or the like.

The first insulating layer IOL1 may include an inorganic film. For example, the first insulating layer IOL1 may be an inorganic film including at least one of aluminum oxide, titanium oxide, silicon oxide, silicon nitride, silicon oxynitride, zirconium oxide, or hafnium oxide. The first insulating layer IOL1 may have a single-layered structure or a multi-layered structure.

The second insulating layer IOL2 may be arranged on the first insulating layer IOL1 and may cover the gate GT. The second insulating layer IOL2 may be commonly overlapped with the pixels. The second insulating layer IOL2 may include an inorganic film. For example, the second insulating layer IOL2 may include at least one of silicon oxide, silicon nitride, or silicon oxynitride. The second insulating layer IOL2 may be an inorganic layer and/or an organic layer and may have a single-layered structure or a multi-layered structure. In one or more embodiments, the second insulating layer IOL2 may have a multi-layered structure including a silicon oxide layer and a silicon nitride layer.

The third insulating layer IOL3 may be arranged on the second insulating layer IOL2. The third insulating layer IOL3 may include an inorganic film. The third insulating layer IOL3 may have a single-layered structure or a multi-layered structure. For example, the third insulating layer IOL3 may have a multi-layered structure including a silicon oxide layer and a silicon nitride layer.

The first connection electrode CNE1 may be arranged on the third insulating layer IOL3. The first connection electrode CNE1 may be connected to the signal line SCL through a first contact hole CH-1 penetrating the first, second, and third insulating layers IOL1, IOL2, and IOL3.

The fourth insulating layer IOL4 may be arranged on the third insulating layer IOL3. The fourth insulating layer IOL4 may include an inorganic film, and the fourth insulating layer IOL4 may also be referred to as a fourth inorganic film. The fourth insulating layer IOL4 may be a single-layered silicon oxide layer.

The fifth insulating layer OML1 may be arranged on the fourth insulating layer IOL4. The fifth insulating layer OML1 may include an organic film. The fifth insulating layer OML1 may be referred to as a first organic film. The first organic film may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin.

The second connection electrode CNE2 may be arranged on the fifth insulating layer OML1. The second connection electrode CNE2 may be connected to the first connection electrode CNE1 through a second contact hole CH-2 passing through the fourth insulating layer IOL4 and the fifth insulating layer OML1.

The sixth insulating layer OML2 may be arranged on the fifth insulating layer OML1 and may cover the second connection electrode CNE2. The sixth insulating layer OML2 may include an organic film. The sixth insulating layer OML2 may be referred to as a second organic film. The second organic film may include at least one of an acrylate-based resin, a methacrylate-based resin, a polyisoprene-base resin, a vinyl-based resin, an epoxy-based resin, a urethane-based resin, a cellulose-based resin, a siloxane-based resin, a polyamide-based resin, or a perylene-based resin.

In one or more embodiments, the circuit layer may further include a plurality of transistors and may further include signal lines electrically connected to the plurality of transistors.

The display layer DP-ED may be arranged on the circuit layer DP-CL. The display layer DP-ED may include a pixel defining layer PDL and a light-emitting element LD. The light-emitting element LD may include a first electrode AE, a light-emitting layer EL, and a second electrode CE.

The first electrode AE may be arranged on the sixth insulating layer OML2. The first electrode AE may be connected to the second connection electrode CNE2 through the third contact hole CH-3 penetrating the sixth insulating layer OML2. The first electrode AE may be electrically connected to the drain DE of the transistor TR through the first and second connection electrodes CNE1 and CNE2.

The first electrode AE may be referred to as a pixel electrode. The first electrode AE may be formed or composed of a metal material, a metal alloy, or a conductive (e.g., electrically conductive) compound. The first electrode AE may be an anode or a cathode. The first electrode AE may be a transmissive electrode, a transflective electrode, or a reflective electrode. If (e.g., when) the first electrode AE is a transmissive electrode, the first electrode AE may include a transparent (e.g., substantially transparent) metal oxide, for example, indium tin oxide (ITO), indium zinc oxide (IZO), zinc oxide (ZnO), indium tin zinc oxide (ITZO), and/or the like. If (e.g., when) the first electrode AE is a transflective electrode or a reflective electrode, the first electrode AE may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg). In one or more embodiments, the first electrode AE may have a multi-layered structure including a reflective film or a semi-transmissive film formed or composed of the material as described in one or more embodiments and a transparent (e.g., substantially transparent) conductive (e.g., electrically conductive) film formed or composed of indium tin oxide (ITO), indium zinc oxide (IZO), zinc oxide (ZnO), indium tin zinc oxide (ITZO), and/or the like. For example, the first electrode AE may have a three-layered structure of ITO/Ag/ITO, but embodiments of the present disclosure are not limited thereto. In one or more embodiments, the first electrode AE may include the metal material as described in one or more embodiments, a combination of two or more metal materials selected from among the metal materials as described in one or more embodiments, or an oxide thereof.

The pixel defining layer PDL may be arranged on the sixth insulating layer OML2. In one or more embodiments, the pixel defining layer PDL may be formed or composed of a polymer resin. For example, the pixel defining layer PDL may be formed or composed of a polyacrylate-based resin and/or a polyimide-based resin. The pixel defining layer PDL may further include an inorganic material in addition to the polymer resin. The pixel defining layer PDL may be formed to include a light absorbing material or may be formed to include a black pigment and/or a black dye. The pixel defining layer PDL, which is formed to include a black pigment and/or a black dye, may serve as a black pixel defining layer. In forming the pixel defining layer PDL, black pigments or the black dyes, such as carbon black, may be utilized, but embodiments of the present disclosure are not limited thereto.

In one or more embodiments, the pixel defining layer PDL may be formed or composed of an inorganic material. For example, the pixel defining layer PDL may be formed to include silicon nitride, silicon oxide, and/or silicon oxynitride.

A pixel opening PX-OP exposing a portion of the first electrode AE may be defined in the pixel defining layer PDL. In the display module DM according to one or more embodiments, the light-emitting regions PXA may be divided by the pixel defining layer PDL. The display module DM may include light emitting regions PXA and a non-light emitting region NPXA, and the non-light emitting region NPXA may be a portion overlapping the pixel defining layer PDL. A portion corresponding to the first electrode AE exposed at the pixel opening PX-OP may be defined as the light emitting region PXA.

In the light-emitting element LD, the light-emitting layer EL may be arranged on the first electrode AE. In one or more embodiments, the light emitting layer EL may be to emit light of at least one color of blue, red, or green.

The second electrode CE may be arranged on the light-emitting layer EL. The second electrode CE may have an integral shape and may be commonly arranged in a plurality of pixels. The second electrode CE may be referred to as a common electrode. The second electrode CE may be a cathode or an anode. For example, if (e.g., when) the first electrode AE is an anode, the second electrode CE may be a cathode, and if (e.g., when) the first electrode AE is a cathode, the second electrode CE may be an anode.

The second electrode CE may be a transmissive electrode, a transflective electrode, or a reflective electrode. If (e.g., when) the second electrode CE is a transmissive electrode, the second electrode CE may be made of a transparent (e.g., substantially transparent) metal oxide, for example, indium tin oxide (ITO), indium zinc oxide (IZO), zinc oxide (ZnO), indium tin zinc oxide (ITZO), and/or the like. In one or more embodiments, the second electrode CE may be formed to include Ag, Mg, Cu, Al, Pt, Pd, Au, Ni, Nd, Ir, Cr, Li, Ca, LiF/Ca, LiF/Al, Mo, Ti, W, or a compound or a mixture thereof (for example, a mixture of Ag and Mg).

In one or more embodiments, a hole control layer may be arranged between the first electrode AE and the light emitting layer EL. The hole control layer may include a hole transport layer and may further include a hole injection layer. An electron control layer may be arranged between the light emitting layer EL and the second electrode CE. The electron control layer may include an electron transport layer and may further include an electron injection layer. The hole control layer and the electron control layer may be formed to be commonly overlapped with a plurality of pixels.

The encapsulation layer TFE may be arranged on the display layer DP-ED. The encapsulation layer TFE may include a first inorganic layer IL1, an organic layer OL, and a second inorganic layer IL2 sequentially stacked. However, the layers constituting the encapsulation layer TFE are not limited thereto.

The inorganic layers IL1 and IL2 may be to protect the display layer DP-ED from moisture and/or oxygen, and the organic layer OL may be to protect the display layers DP-ED from foreign substances, such as dust particles. The inorganic layers IL1 and IL2 may include at least one of silicon nitride, silicon oxynitride, silicon oxide, titanium oxide, or aluminum oxide. The organic layer OL may include an acrylate-based organic material. However, the types (kinds) of materials constituting the inorganic layers IL1 and IL2 and the organic layer OL are not limited thereto.

An input sensor TP may be arranged on the encapsulation layer TFE. In one or more embodiments, the input sensor TP may include sensor conductive layers MTL1 and MTL2 and a plurality of sensor insulating layers ISL.

In FIG. 6, the input sensor TP is illustrated in a multi-layered structure including a first sensor conductive layer MTL1 and a second sensor conductive layer MLT2. The second sensor conductive layer MTL2 may be in contact with the first sensor conductive layer MLT1 through the contact hole CNT. However, embodiments of the present disclosure are not limited thereto, and the input sensor TP may include a single-layered sensor conductive layer. In this case, one selected from among the sensor insulating layers ISL-C and ISL-T may not be provided.

Each of the first sensor conductive layer MTL1 and the second sensor conductive layer MLT2 may have a single-layered structure or a multi-layered structure. The sensor conductive layer having a multi-layered structure may be one in which two or more transparent (e.g., substantially transparent) conductive (e.g., electrically conductive) layers and/or metal layers are stacked. For example, the sensor conductive layer may have a structure in which a transparent (e.g., substantially transparent) conductive (e.g., electrically conductive) layer and a metal layer are stacked, or a structure in which metal layers including different metals are stacked.

The transparent conductive layer included in the first sensor conductive layer MTL1 and the second sensor conductive layer MLT2 may include indium tin oxide (ITO), indium zinc oxide (IZO), zinc oxide (ZnO), indium tin zinc oxide (ITZO), poly(3,4-ethylenedioxythiophene) (PEDOT), metal nanowires, and/or graphene. Molybdenum, silver, titanium, copper, aluminum, or an alloy thereof may be included as a metal layer included in the first sensor conductive layer MTL1 and the second sensor conductive layer MLT2.

Among the first sensor conductive layer MTL1 and the second sensor conductive layer MTL2 having a multilayer structure, a metal having relatively high durability and low reflectance may be applied to an outer layer of the sensor conductive layer, and a metal having high electrical conductivity may be applied to the inner layer of the sensor conducting layer. For example, each of the first sensor conductive layer MTL1 and the second sensor conductive layer MTL2 may have a three-layer structure composed of titanium/aluminum/titanium.

In one or more embodiments, the sensor insulating layer ISL may include a first sensor insulating layer ISL-B arranged under the first sensor conductive layer MTL1, a second sensor insulating layer ISL-C arranged over the first sensor conductive layers MTL1, and a third sensor insulating layer ISL-T arranged over the second sensor conductive layers MTL2. The third sensor insulating layer ISL-T may correspond to the uppermost sensor insulating layer in the input sensor TP.

The first sensor insulating layer ISL-B may be referred to as a sensor base layer. The first sensor insulating layer ISL-B may be arranged directly on the encapsulation layer TFE. For example, the first sensor insulating layer ISL-B may be arranged directly on the second inorganic layer IL2 of the encapsulation layer TFE.

Each of the first sensor insulating layer ISL-B and the second sensor insulating layer ISL-C may include an inorganic film. In one or more embodiments, each of the first sensor insulating layer ISL-B and the second sensor insulating layer ISL-C may further include an organic film.

The first sensor insulating layer ISL-B and the second sensor insulating layer ISL-C may include at least one of silicon nitride (e.g., SiₓN_{y}, wherein 0<x≤3 and 0<y≤4; e.g., Si₃N₄) or silicon oxynitride (e.g., SiₓON_{y}, wherein 0<x≤2 and 0≤y≤2; e.g., SiON or Si₂N₂O), respectively. In one or more embodiments, the first sensor insulating layer ISL-B and the second sensor insulating layer ISL-C may include silicon oxide (e.g., SiOₓ, wherein 0<x≤2; e.g., SiO₂). The first sensor insulating layer ISL-B and the second sensor insulating layer ISL-C may include at least one of aluminum oxide, titanium oxide, zirconium oxide, or hafnium oxide as an inorganic film. X and Y in the representations of silicon nitride (SiₓN_{y}), silicon oxynitride (SiₓON_{y}), and silicon oxide (SiO_{X}) may each be greater than 0.

If (e.g., when) the first sensor insulating layer ISL-B and the second sensor insulating layer ISL-C include an organic film, the organic film may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

In one or more embodiments, the third sensor insulating layer ISL-T to be the uppermost layer of the input sensor TP may include an epoxy-based compound. The third sensor insulating layer ISL-T may be formed to include an epoxy acrylate polymer. In one or more embodiments, the third sensor insulating layer ISL-T may be formed to include an epoxy urethane acrylate polymer.

In one or more embodiments, the third sensor insulating layer ISL-T, which is the uppermost sensor insulating layer, may be formed from (or made from) an epoxy acrylate composition including an acrylate-based monomer having an epoxy group, acrylic acid, and isocyanate. The epoxy acrylate composition may optionally further include additives, such as an initiator, a curing agent, a coupling agent, a flame retardant, a light absorber, or a surfactant in addition to the main (or major) component including an acrylate-based monomer, acrylic acid, and isocyanate.

In one or more embodiments, the epoxy acrylate composition forming the third sensor insulating layer ISL-T may include, as a main or predominant component, compounds of Compound Group A. In one or more embodiments, the third sensor insulating layer ISL-T may be formed by photocuring an epoxy acrylate composition, which includes, as a main (or major) component (e.g., as major components), compounds of Compound Group A and other additives.

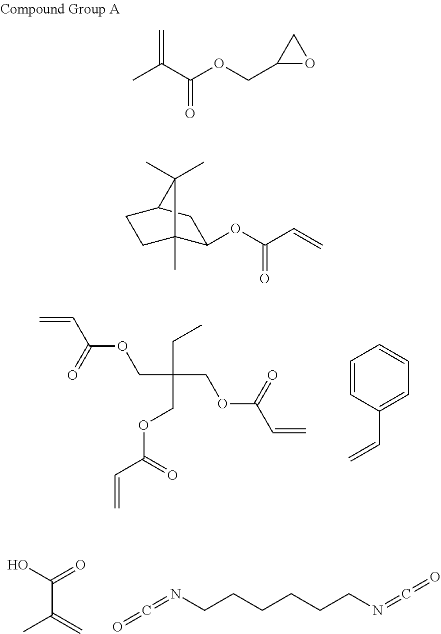

In one or more embodiments, the epoxy acrylate composition forming the third sensor insulating layer ISL-T may include compounds of Compound Group B as a main (or major) component. In one or more embodiments, the third sensor insulating layer ISL-T may be formed by photocuring an epoxy acrylate composition containing the compounds of Compound Group B as a main (or major) component and a composition containing other additives.

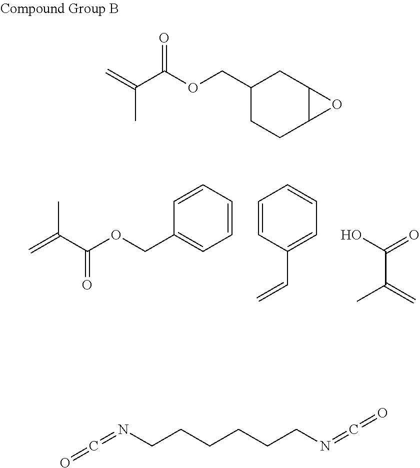

The main group of the compounds of Compound group B differs from the main group of the compounds of Compound Group A in the type (kind) of the acrylate monomer containing an epoxy group, and the compounds of Compound Group B are characterized by including a benzyl methacrylate monomer in place of an isobornyl acrylate and multi-functional acrylate monomer included in the compounds of Compound Group A. For example, the main group of the compounds of Compound Group B differs from the main group of the compounds of Compound Group A in that they include, as a main group, an acrylate-based monomer containing an aromatic group (such as benzyl group).

In one or more embodiments, the third sensor insulating layer ISL-T, which is the uppermost sensor insulating layer, may be arranged in the entire active region AA-EA (see FIG. 5) and the peripheral region NAA-EA (see FIG. 5) of the electronic device. In the peripheral region NAA-EA (see FIG. 5), the third sensor insulating layer ISL-T may cover a part of the configuration or arrangement of the circuit layer DP-CL (see FIG. 5) or may be directly arranged on a part of the exposed base layer BS (FIG. 5).

In the display module DM of one or more embodiments, the cover layer SIP may be directly arranged on the input sensor TP. In one or more embodiments, the cover layer SIP may be directly arranged on the third sensor insulating layer ISL-T, which is the uppermost insulating layer. The cover layer SIP may be arranged directly on the entire upper surface of the third sensor insulating layer ISL-T, which is the uppermost insulating layer. In one or more embodiments, the cover layer SIP may exhibit excellent or suitable bonding strength with respect to the third sensor insulating layer ISL-T formed to include the epoxy-based compound.

The cover layer SIP may include an acrylate-based polymer. The cover layer SIP may include an acrylate-based polymer and a silane coupling agent, an acrylate-based polymer and an epoxy-based compound, or an acrylate-based polymer and a polymer derived from aromatic monomer. In one or more embodiments, the cover layer SIP may include an epoxy acrylate-based polymer. For example, the cover layer SIP may be formed by including an epoxy acrylate copolymer. In one or more embodiments, if (e.g., when) the cover layer SIP includes an epoxy acrylate-based polymer, the silane coupling agent, additional epoxy-based compound, or polymer derived from an aromatic monomer, as described in one or more embodiments, may not be included. A polymer derived from an aromatic monomer may correspond to a compound formed by polymerizing a monomer containing an aromatic ring.

As used herein, the terms “main component” refers to a component that is present in a composition, a polymer, or a product in an amount greater than an amount of any other single component in the composition or product. In contrast, the term “primary component” refers to a component that makes up at least 50% (wt % or at %) or more of the composition, polymer, or product.

Referring to FIG. 6, the display module DM of one or more embodiments may include a low-reflection member ARM arranged on the cover layer SIP. The low-reflection member ARM may be arranged directly on the cover layer SIP. In one or more embodiments, the low-reflection member ARM may include the polarizing plate PL and the interlayer adhesive layer AP-P, but embodiments of the present disclosure are not limited thereto, and the interlayer adhesive layers AP-P may not be provided.

Referring to FIG. 5 and/or the like, the cover layer SIP may be directly arranged between the low-reflection member ARM and the input sensor TP in the entire active region AA-EA and the peripheral region NAA-EA. The cover layer SIP may bond the input sensor TP and the low-reflection member ARM with sufficient or suitable strength even in the peripheral region NAA-EA, and thus the display module DM of one or more embodiments and the electronic device EA including the display module DM may exhibit excellent or suitable impact strength characteristics.

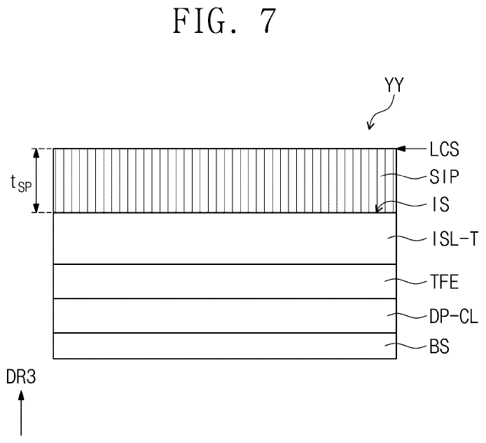

FIG. 7 is a cross-sectional view illustrating a portion of a display module according to one or more embodiments. FIG. 7 illustrates a portion corresponding to the YY region of FIG. 5. For example, FIG. 7 illustrates a stacked-layer structure of a part of the display module in the peripheral region NAA-EA (see FIG. 5).

Referring to FIG. 7, the cover layer SIP may be directly arranged on the third sensor insulating layer ISL-T, which is the uppermost sensor insulating layer of the input sensor. Even in the peripheral region NAA-EA (see FIG. 5), the cover layer SIP may be provided with a sufficient or suitable thickness to provide a flat (e.g., substantially flat) surface to the layer on top of the cover layer SIP. In one or more embodiments, the thickness tsp of the cover layer SIP may be about 10 μm or more. For example, the thickness tsp of the cover layer SIP may be about 15 μm or more. As the cover layer SIP is arranged to have a thickness tsp of about 10 μm or more, it may have sufficient or suitable strength and may cover the bending of the lower portion of the cover layer SIP to provide an excellent or suitable flat (e.g., substantially flat) surface.

The cover layer SIP may be formed or arranged by providing the acrylate-based composition utilizing an inkjet printing method and then ultraviolet curing of the acrylate-based composition. Accordingly, the cover layer SIP may be formed to have a sufficient or suitable thickness.

The cover layer SIP may be formed from (or made from) an acrylic composition including at least one selected from among the compounds of Compound Group C. The cover layer SIP may be formed by ultraviolet curing an acrylic composition containing at least one selected from among the compounds of Compound Group C.

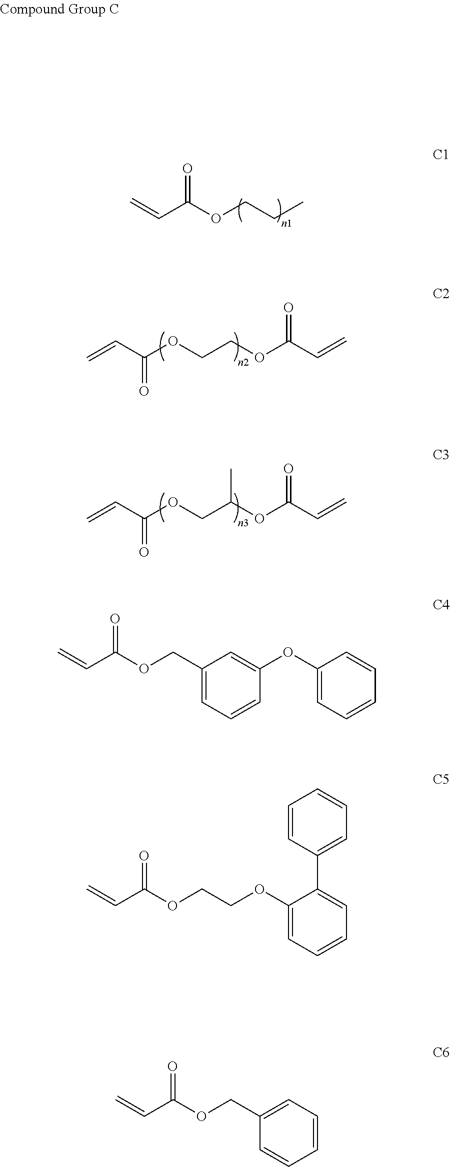

In compound C1, n1 may be an integer of 5 or more, in compound C2, n2 may be an integer of 3 or more, and in compound C3, n3 may be an integer of 2 or more.

In one or more embodiments, the cover layer SIP may be formed from (or made from) an acrylic composition including the compounds C1, C2, and C3 of Compound Group C, or may be formed from (or made from) acrylate-based compositions including the compounds C4, C5, and C6 of Compound Group C, or may be formed from (or made from) acrylate-based compositions containing the compounds C6 and C1 of Compound Group C.

The cover layer SIP may be arranged directly on the third sensor insulating layer ISL-T and may exhibit a characteristic of excellent or suitable bonding strength with the third sensor insulating layers ISL-T. In one or more embodiments, a covalent bond may be formed between the third sensor insulating layer ISL-T and the cover layer SIP at the interface IS between the third sensor insulating layer ISL-T and the cover layer SIP. For example, a covalent bond may be formed between the silane coupling agent and the third sensor insulating layer ISL-T, between the epoxy compound and the third sensor insulating layer ISL-T, or between the epoxy acrylate and the third sensor insulating layer ISL-T. For example, if (e.g., when) the third sensor insulating layer ISL-T is formed or composed mainly or predominantly of the compounds of Compound Group A or Compound Group B as described in one or more embodiments, the third sensor insulating layers ISL-T may include epoxy functional groups, and the epoxy functional groups of the third sensor insulating layer ISL-T may form a covalent bond with the silane coupling agent or the epoxy functional group of the cover layer SIP.

The configuration or arrangement of the cover layer SIP according to one or more embodiments may increase the chemical bonding strength as compared to only forming a hydrogen bond with the lower third sensor insulating layer ISL-T if (e.g., when) formed only of an acrylate polymer without including a silane coupling agent or an epoxy group.

In one or more embodiments, the epoxy compound included in the cover layer SIP may have the following structure.

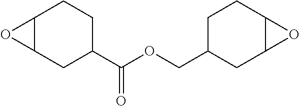 [SMILES: O=C(OCC1CCC2OC2C1)C1CCC2OC2C1]

In one or more embodiments, if (e.g., when) the third sensor insulating layer ISL-T is formed mainly or predominantly of the compounds of Compound Group B, the cover layer SIP may include a polymer derived from an aromatic monomer. The aromatic polymer of the cover layer SIP may reduce the modulus of the cover layer, thereby enhancing shock absorption in the cover layer SIP. In one or more embodiments, if (e.g., when) the cover layer SIP includes an aromatic polymer, a bonding strength may be generated between the aromatic polymer and the aromatic ring of the compound of Compound Group B by a TT-IT interaction, thereby increasing the bonding strength between the third sensor insulating layer ISL-T and the cover layer SIP.

In the display module according to one or more embodiments, the cover layer SIP may exhibit excellent or suitable bonding strength characteristics according to chemical bonding with the third sensor insulating layer ISL-T, which includes a silane coupling agent and an acrylate-based polymer; an epoxy-based compound and an acrylate-based polymer; or an epoxy-based compound including an epoxy acrylate-based polymer. In one or more embodiments, if (e.g., when) the third sensor insulating layer ISL-T is formed or composed of an epoxy-based compound containing an aromatic group (e.g., a phenyl group), the cover layer SIP may include an acrylate-based polymer and a polymer derived from an aromatic monomer to exhibit strong bonding strength characteristics to the third sensor insulating layers ISL-T.

An edge of the input sensor TP (see FIG. 5) and an edge of the cover layer SIP may overlap each other on one side of the peripheral region NAA-EA (see FIG. 5). For example, the edge of the input sensor TP and the edge of the cover layer SIP (see FIG. 5), which together constitute the edge of the display module DM, may be positioned on substantially the same surface.

Referring to FIG. 7, in one or more embodiments, the edge line LCS may be an edge line of the display module DM (see FIG. 5). In one or more embodiments, edge lines of the base layer BS, the circuit layer DP-CL, the encapsulation layer TFE, the third sensor insulating layer ISL-T, and the cover layer SIP may overlap each other. In one or more embodiments, the edge line LCS may be a portion corresponding to a portion irradiated with a laser in a laser cutting process.

The display module according to one or more embodiments, due to the excellent or suitable bonding strength characteristic between the input sensor including the third sensor insulating layer and the cover layer, the bonding strength between two adjacent layers may be strongly or suitably maintained even after laser cutting, whereby the display module may exhibit superior or suitable impact resistance characteristics.

The display module according to one or more embodiments as described with reference to FIGS. 5 to 7 may be to generate and provide an image. The electronic device EA (see FIG. 1) of one or more embodiments may include the display module DM (see FIG. 5) of one or more embodiments and the power module PM (see FIG. 1), which supplies power to the display module. The electronic device EA (see FIG. 1) according to one or more embodiments may include the display module DM (see FIG. 5) according to one or more embodiments as described in one or more embodiments to exhibit excellent or suitable impact resistance and improved or enhanced reliability quality characteristics.

Tables 1 and 2 show comparative evaluation results of physical properties between Examples having a stacked-layered structure of a top sensor insulating layer and a cover layer according to one or more embodiments of the present disclosure, and Comparative Examples having different cover layer structures from those of the Examples.

The uppermost sensor insulating layer in Comparative Example 1 and Examples 1-1 to 1-3 in Table 1 includes an epoxy urethane acrylate polymer. The uppermost sensor insulating layer used in the evaluation of Comparative Example 1 and Examples 1-1 to 1-3 includes the compounds of Compound Group A as a main or predominant composition, and is formed by photocuring the composition including the main (or major) component (or major composition).

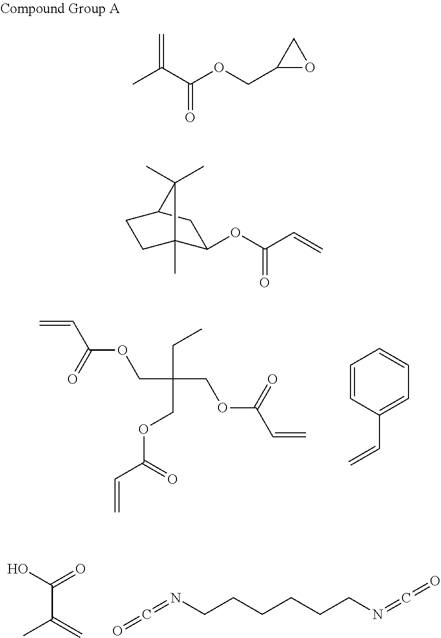

The composition used for forming the uppermost sensor insulating layer may include, in addition to the main or predominant compounds of Compound Group A, a curing agent and a photoinitiator, and may further include at least one of additives, such as a coupling agent, a flame retardant, an ultraviolet absorber, an ionic initiator, or a surfactant.

Comparative Example 1 has a cover layer including only an acrylate-based polymer. The acrylate-based polymer of the cover layer in Comparative Example 1 does not contain an aromatic group, such as a phenyl group. The cover layer of Comparative Example 1 contains an acrylate-based polymer formed mainly or predominantly of the compounds C1, C2, and C3 of Compound Group C as described herein.

Example 1-1 includes an acrylate-based polymer and a silane coupling agent in the cover layer, Example 1-2 includes an acrylate-based polymer and an epoxy-based compound in the cover layer, and Example 1-3 includes an epoxy acrylate-based polymer in the cover layer.

In Table 1, peel strength and Young's modulus were measured with a Universal Testing Machine (UTM), and elastic modulus and hardness were measured with a Nano Indentation Tester (NID). Ultra Nano Indenter (UNHT) from Anton-Paar was used as the nano indenter used for the measurement of elastic modulus and hardness.

The peel strength was evaluated by a 180° peel off method using UTM. Samples of Comparative Example 1 and Examples 1-1 to 1-3 were provided on a glass substrate at a width of 25 mm, and then a pressure-sensitive adhesive substrate was attached on top of the provided sample to measure the force of peeling the samples of Comparative Example 1 and Example 1-1 to Example 1-3 from the glass substrate at a rate of 300 mm/min. The peel strength in Table 1 was measured at room temperature.

The Young's modulus was measured after cutting the samples of Comparative Example 1 and Examples 1-1 to 1-3 according to the ISO527-3 type (kind) 5 standard and mounting them on a UTM. The mounted specimens were tensioned at a rate of 5 mm/min to measure Young's modulus in the range of 0.05% to 0.5% elongation. The measured value corresponds to an average value after three or more measurements. The Young's modulus was measured at room temperature.

Samples of Comparative Example 1 and Examples 1-1 to 1-3 were cut to 2 cm×2 cm, and the samples were attached to a sample stud. After placing and securing the sample on the sample holder, the surface condition was checked using a microscope, and a clean area of the surface was selected as the analysis position. Then, the modulus and hardness were measured. Berkovich was used as the indenter of the Nano Indenter. The elastic modulus and hardness were measured at 15 points after holding and pressing for 60 seconds at a maximum load of 2 mN, and then averaged. The loading and unloading rates of the indenters were set to 20 mN/min.

TABLE 1

| catego- | Comparative | | | Examples |
|---|---|---|---|---|
| rization | Example 1 | Example 1-1 | Example 1-2 | 1-3 |
| Peel | 20.2 ± 0.9 | 38.7 ± 9.6 | 44.1 ± 18.7 | 280 or More |
| strength | | | | |
| (gf/in) | | | | |
| Young's | 1.40 | 0.10 | 1.21 | 1.49 |
| modulus | | | | |
| (GPa) | | | | |
| Elastic | 3.27 ± 0.03 | 0.66 ± 0.01 | 0.55 ± 0.02 | 2.16 ± 0.02 |
| Modulus | | | | |
| (GPa) | | | | |
| Hardness | 0.077 ± 0.001 | 0.023 ± 0.0001 | 0.016 ± 0.0001 | 0.04 ± 0.001 |
| (GPa) | | | | |

Referring to the results in Table 1, Examples 1-1 to 1-3 exhibited high peel strength, low elastic modulus, and low hardness properties as compared to Comparative Example 1. Also, Examples 1-1 and 1-2 exhibited low Young's modulus characteristics as compared with Comparative Example 1. In the case of Example 1-3, the Young's modulus was slightly higher than that of Comparative Example 1, but the peeling strength was significantly or substantially increased compared to that of Comparative Example 1. The increase in peeling strength in Examples 1-1 to 1-3 as compared with Comparative Example 1 is considered to be due to the difference in bonding between the cover layer and the uppermost sensor insulating layer. The cover layer in Comparative Example 1 forms a hydrogen bond with the uppermost insulating layer, and in comparison, in the case of Examples 1-1 to 1-3, a covalent bond can be formed between the cover layer and the uppermost sensor insulating layer. Accordingly, it is considered that the strength of the bond between two adjacent layers is increased, and the peeling strength of the cover layer is increased in the Examples.

In the case of the Examples, a silane coupling agent or an epoxy compound was included as an additional component in addition to the acrylate-based polymer, or the cover layer was formed or composed of an epoxy acrylate-based polymer including an epoxy group as a polymer repeating unit, and thus, a small elastic modulus and a small hardness value were exhibited as compared with the Comparative Example, and thus, it is expected that the Examples may exhibit excellent or suitable impact resistance as compared with the Comparative Example.

In Comparative Example 2 and Examples 2-1 to 2-3 in Table 2, the uppermost sensor insulating layer includes an epoxy urethane acrylate polymer. The uppermost sensor insulating layer used in the evaluation of Comparative Example 2 and Examples 2-1 to 2-3 is formed by photocuring a composition containing Compound Group B in a main or predominant component.

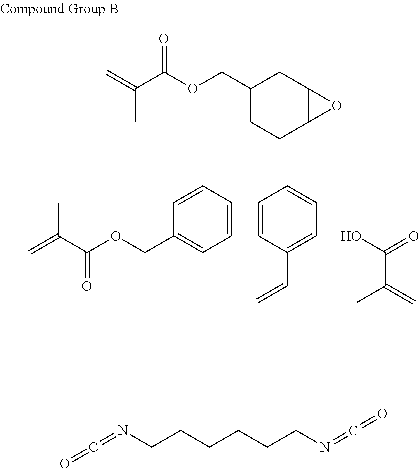

The composition used for forming the uppermost sensor insulating layer contains, in addition to the main or predominant compounds of Compound Group B, a curing agent, and a photoinitiator, and further contains at least one of additives, such as a coupling agent, a flame retardant, an ultraviolet absorber, an ionic initiator, or a surfactant.

The top sensor insulating layer formed from (or made from) the composition containing Compound Group B as a main or major component is different from the top sensor insulating layer used in the evaluation of Table 1 in that it further contains an aromatic ring.

Comparative Example 2 corresponds to a cover layer containing only an acrylate-based polymer. The cover layer of Comparative Example 2 contains an acrylate-based polymer formed mainly or predominantly of the compounds C1, C2, and C3 of Compound Group C as described herein.

Example 2-1 includes an acrylate-based polymer and a silane coupling agent in a cover layer, Example 2-2 includes an acrylate-based polymer and an epoxy compound in the cover layer, and Example 2-3 includes an acrylate-based polymer formed or composed of the compounds C4, C5, and C5 of Compound Group C as described herein as a main (or major) component in the cover layer. For example, the cover layer of Example 2-3 contains an acrylate-based polymer and a polymer derived from an aromatic monomer.

In Table 2, peel strength and Young's modulus were measured with a universal testing machine (UTM). The peel strength in Table 2 is a 90° peeling strength evaluation result. There is a difference in the peeling direction as compared with the peel strength evaluation method in Table 1. The Young's modulus is substantially the same as the evaluation method used in the description of Table 1.

TABLE 2

| | Comparative | Example | Example | Example |
|---|---|---|---|---|
| categorization | Example 2 | 2-1 | 2-2 | 2-3 |
| Peel strength | 48.2 | 55.5 | 66.6 | 75.3 |
| (gf/mm) | | | | |
| Young's | 1.40 | 0.24 | 0.35 | 0.57 |
| modulus | | | | |
| (GPa) | | | | |

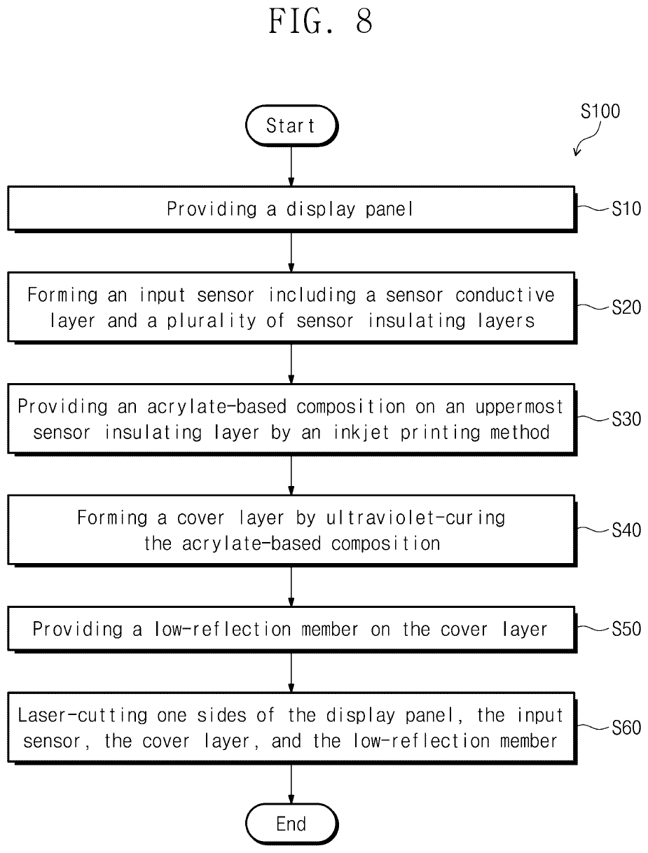

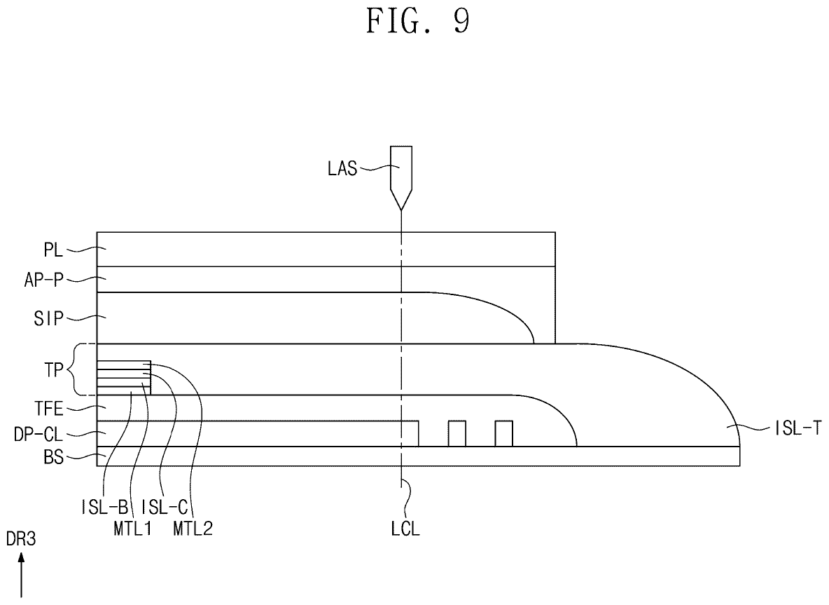

Referring to the results in Table 2, strong peel strength properties and low Young's modulus values were exhibited for Examples 2-1 to 2-3 as compared to Comparative Example 2. For example, it can be seen that, compared to Comparative Example 2, if (e.g., when) the composition of the cover layer is changed, an increased or enhanced peel strength characteristic is exhibited with respect to the uppermost sensor insulating layer. Also, it can be seen that in the case of Examples, the modulus decreased as the Young's modulus value was lower than that of Comparative Example 2. Accordingly, it can be said that the Examples exhibit superior strength and superior impact resistance properties as compared with Comparative Example 2. FIG. 8 is a flowchart illustrating a method of manufacturing a display module according to one or more embodiments. FIG. 9 is a diagram exemplarily illustrating one step (e.g., act or task) of a display module manufacturing method according to one or more embodiments. In the following description of a method for manufacturing a display module according to one or more embodiments, which will be described in more detail with reference to FIGS. 8 and 9, overlapping content (e.g., amount) with the description those described with reference to FIG. 1 to FIG. 7 may not be described again, and differences may be mainly or predominantly described.

Referring to FIG. 8, a display module manufacturing method S100 of one or more embodiments may include providing a display panel S10, forming an input sensor including a sensor conductive (e.g., electrically conductive) layer and a plurality of sensor insulating layers S20, providing an acrylate-based composition on an uppermost sensor insulating (e.g., electrically insulating) layer by an inkjet printing method S30, forming a cover layer by ultraviolet-curing the acrylate-based composition S40, providing a low-reflection member on the cover layer S50, and laser-cutting one side of the display panel, the input sensor, the cover layer and the low-reflection member S60.

A display panel may be produced by forming a display layer including a light-emitting element and forming an encapsulation layer on the display layer. The step (e.g., act or task) S10 of providing the display panel may be a step (e.g., act or task) of providing a display panel including a display layer and an encapsulation layer arranged on the display layer.

The forming an input sensor S20 may be a step (e.g., act or task) of forming an input sensor including a sensor conductive (e.g., electrically conductive) layer and a plurality of sensor insulating (e.g., electrically insulating) layers on a display panel. The input sensor may be formed directly on the display panel. The input sensor may be formed directly on the encapsulation layer of the display panel. The input sensor may be formed by patterning the sensor conductive layer and sequentially providing sensor insulating (e.g., electrically insulating) layers. In one or more embodiments, the uppermost sensor insulating layer may be formed or composed of an epoxy-based compound.

After forming the input sensor S20, the providing the acrylate-based composition by an inkjet printing method S30 may be performed. An acrylate-based composition may be provided on top of the uppermost sensor insulating layer of the input sensor by inkjet printing. The provided acrylate-based composition may include an acrylate-based monomer and may include at least one of a silane coupling agent, an epoxy-based monomer, or an aromatic monomer. In one or more embodiments, the provided acrylate-based composition may be one including an epoxy acrylate-based monomer. The acrylate-based composition may contain a photoinitiator and a curing agent in addition to the main (or major) component as described herein. In one or more embodiments, the acrylate-based composition may further include additives other than the main (or major) component, the photoinitiator, and the curing agent as described herein.

After the acrylate-based composition is directly provided to the front surface of the uppermost sensor insulating layer of the input sensor by an inkjet printing method, forming a cover layer by ultraviolet-curing the provided acrylate-based composition S40 to form a cover layer may be performed.

The cover layer SIP formed by ultraviolet-curing the acrylate-based composition may exhibit excellent or suitable bonding strength to the uppermost sensor insulating layer. The cover layer may further contain a silane coupling agent, an epoxy compound, or an aromatic polymer in addition to the acrylate-based polymer or may be formed so as to contain an epoxy acrylate-based polymer and may have a strong chemical bonding strength to the uppermost sensor insulating layer formed or composed of the epoxy-based compound, and thus may exhibit excellent or suitable bonding characteristics.

In one or more embodiments, the forming a cover layer by ultraviolet-curing the provided acrylate-based composition S40 may proceed while supplying nitrogen (N₂). For example, in one or more embodiments, the forming a cover layer by ultraviolet-curing the provided acrylate-based composition S40 may be performed by supplying nitrogen (N₂) for a set or predetermined time so that (e.g., such that) the oxygen (O₂) content (e.g., amount) is 10% or less in an air component in an atmosphere in which curing is performed. For example, in the method for manufacturing a display module according to one or more embodiments, forming a cover layer by ultraviolet-curing the provided acrylate-based composition S40 may proceed in a state in which nitrogen (N₂) is supplied or while nitrogen (N₂) continues to be supplied so as to have an oxygen (O₂) content (e.g., amount) lower than that in a general air atmosphere, so that (e.g., such that) the degree of curing in the acrylate-based composition may be increased.

The degree of curing of the acrylate-based composition forming the cover layer may be about 95% or more. In the case of the cover layer formed by supplying nitrogen (N₂) for a set or predetermined time so that (e.g., such that) the oxygen (O₂) content (e.g., amount) is about 10% or less in the air component in the atmosphere in which curing is performed, the acrylate-based composition may exhibit high degree of curing characteristics as the oxygen content (e.g., amount) is reduced even on the exposed upper surface compared to that in normal air.

For example, as the cover layer exhibits a high degree of curing of about 95% or more throughout its entirety, it may demonstrate excellent or suitable thermal stability. Accordingly, damage to the cover layer due to deterioration may be minimized or reduced even in the laser cutting process as described herein.

Table 3 shows the evaluation results of the cover layer formed under the process conditions of the Comparative Example Condition and the Example Condition. The Comparative Example Condition in Table 3 are that ultraviolet curing was performed in a normal air condition, and the concentration of oxygen (O₂) in the Comparative Example Condition is about 20%. Also, the Example Condition was that nitrogen (N₂) was supplied to the air, and nitrogen was supplied for 90 seconds from the start of curing, so that (e.g., such that) the concentration of oxygen (O₂) was decreased to about 20%, about 10%, and about 6% over time.

The degree of curing and decomposition temperature in Table 3 were obtained by evaluating and analyzing the single-layer form of the cover layer, and the NID peel strength was obtained by evaluating after the cover layer was formed on the uppermost sensor insulating layer. The NID peel strength is a value obtained by measuring the load until the NID tip is positioned between the uppermost sensor insulating layer and the cover layer at the side edge and the interface between the uppermost sensor insulating layer and the cover layers is separated.

The NID peel strength was evaluated using the UNHT equipment used for the evaluation of elastic modulus and Young's modulus in Table 1. In the evaluation of the NID peel strength, the evaluation sample was placed between the slide glass and aligned so that (e.g., such that) the measurement part and the surface of the slide glass were flat. Thereafter, the specimen was fixed to the sample holder in the longitudinal direction (the direction in which the interface for measurement was exposed) and then moved to the measurement location for evaluation. The tip radius of the NID tip used was 2 μm.

The maximum load (Max Lod) in the NID peel strength evaluation was 95 mN, and the loading and unloading speed was 950 mN/min. The NID peel strength in Table 3 corresponds to a value obtained by measuring and averaging seven points per sample.

TABLE 3

| | Comparative | Example |
|---|---|---|
| Categorization | Example Condition | Condition |
| Degree of curing at the upper | 88.6 ± 2.2 | 97.6 ± 0.5 |
| portion of cover layer (%) | | |
| Degree of curing at the lower | 95.4 ± 1.2 | 95.6 ± 1.4 |
| portion of cover layer (%) | | |
| 0.5 wt % decomposition | 116.8 ± 2.07 | 123.7 ± 1.26 |
| temperature of cover layer (° C.) | | |
| 1.0 wt % decomposition | 142.3 ± 2.63 | 147.6 ± 2.76 |
| temperature of cover layer (° C.) | | |
| 5.0 wt % decomposition | 232.9 ± 4.00 | 237.1 ± 3.59 |
| temperature of cover layer (° C.) | | |
| Young's modulus (MPa) | 2.92 ± 0.03 | 3.41 ± 0.04 |
| Total Degradation (A.U) | 181059325 | 129204725 |
| NID Peel Strength (mN) | 69.0 | 85.8 |

Referring to the results in Table 3, the cover layer formed by ultraviolet curing under the Example Condition exhibited an overall high degree of curing as compared with the cover layer cured under the Comparative Example Condition. Also, the pyrolysis temperature at which substantially the same amount of decomposition occurs was also higher in the Example Condition. The cover layer formed under the Example Condition exhibited higher Young's modulus characteristics than the cover layer formed in the Comparative Example Condition, which is considered to be due to an increase in the strength of the cover layer resulting from the improved or enhanced degree of curing.

The cover layer formed under the Example Condition exhibited superior NID peel strength characteristics as compared with the cover layer formed in the Comparative Example Condition. This is thought to be because the strength of the cover layer increased due to the improved or enhanced degree of curing, and thus the bonding strength to the uppermost sensor insulating layer increased.

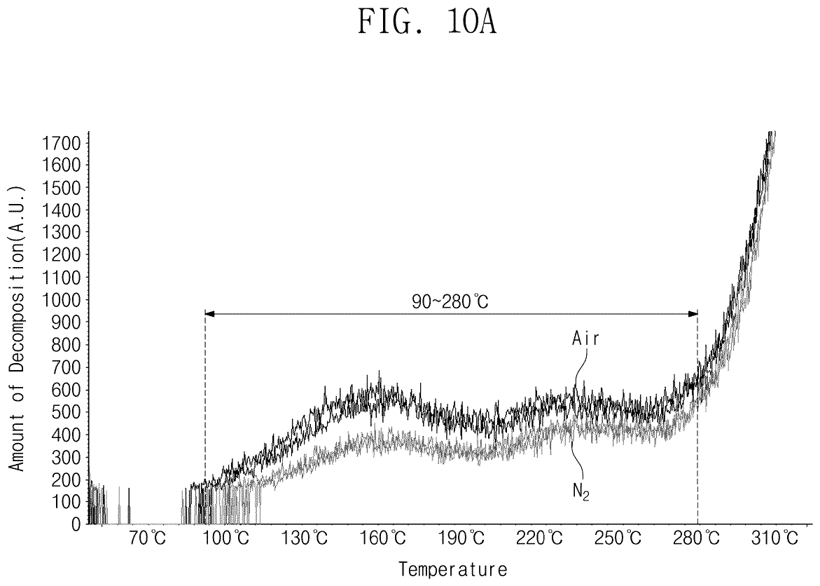

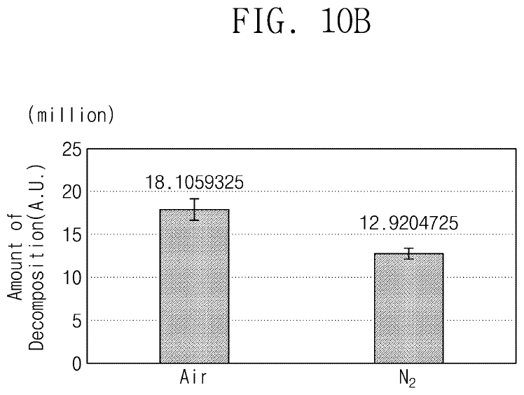

The total decomposition amount indicates the decomposition amount of the cover layer according to the temperature increase, and the total decomposition amount is based on the thermal stability evaluation results shown in FIGS. 10A and 10B.

FIGS. 10A and 10B are diagrams showing evaluation results of the thermal stability of the cover layer. FIG. 10A shows a comparison of the amount of decomposition of the cover layer according to the temperature increase. The portion referred to as “Air” in FIG. 10A is a case where the acrylate-based composition is cured in air to form a cover layer, and the portion referred to as “N₂” is a case where N₂ is provided so that (e.g., such that) the oxygen (O₂) content (e.g., amount) is 10% or less to cure the acrylate composition to form a cover layer. FIG. 10B is a graph showing a comparison of decomposition amounts of monomers constituting the cover layer which were decomposed and detected in a temperature range of 90° C. to 280° C.

Referring to FIG. 10A, it was found that the amount of decomposition if (e.g., when) the acrylate-based composition was cured by providing N₂ in the entire temperature range of 90° C. to 280° C. was smaller than the amount of decomposition in the case where the acrylate-based composition was cured in air to form a cover layer. Referring to FIGS. 10A and 10B, it can be seen that the total amount of decomposition if (e.g., when) the cover layer is formed by curing the acrylate-based composition by providing N₂ is significantly or substantially reduced as compared with the amount of decomposition if (e.g., when) a cover layer is formed in air by curing an acrylate-based composition.

This is because in the case of a cover layer formed by supplying nitrogen (N₂) for a set or predetermined time so that (e.g., such that) ultraviolet-curing proceeds, a high degree of curing may be obtained, and thus the cover layer may have improved or enhanced thermal stability.

A low-reflection member may be provided on the cover layer formed by ultraviolet-curing. The providing the low-reflection member S50 may be a step (e.g., act or task) of providing by attaching or directly arranging the low-reflection member on the cover layer. In one or more embodiments, the low-reflection member may include a polarizing plate and an interlayer adhesive layer, and the interlayer adhesive layer may be attached to the cover layer.

A laser-cutting S60 may be performed after attachment of the low-reflection member. FIG. 9 exemplarily illustrates the laser-cutting S60. Referring to FIG. 9, the laser-cutting S60 may include laser-cutting one sides of a display panel, an input sensor, a cover layer, and a low-reflection member that are sequentially stacked. For example, the laser-cutting is performed on the one sides of the display panel, the input sensor, the cover layer, and the low-reflection member such that cross-sectional profiles of the display panel, the input sensor, the cover layer, and the low-reflection member are aligned.

Also, in the laser cutting S60, one side of the display panel including the base layer BS, the circuit layer DP-CL, and the encapsulation layer TFE, one side of the third sensor insulating layer ISL-T that is the uppermost sensor insulating layer of the input sensor TP, one side of a cover layer SIP, and one sides of the interlayer adhesive layer AP-P and a polarizing plate PL in the low-reflection member may be cut to match each other.

The cutting line LCL may correspond to a portion where the laser LAS is provided. An edge line LCS (see FIG. 7) may be defined by the cutting line LCL. A laser LAS may be provided in the cutting line LCL portion to cut the display panel, the input sensor, the cover layer, and the low-reflection member in the peripheral region NAA-EA (see FIG. 5) so as to have a matched edge line, whereby the area of the peripheral regions NAA-EA in the display module and the electronic device finally manufactured may be reduced. In the display module manufactured by the display module manufacturing method according to one or more embodiments, because the bonding strength between the cover layer and the uppermost sensor insulating layer is high, desorption of the interface between the input sensor and the cover layer after laser-cutting may not occur even if (e.g., when) the attachment area is reduced.

The display module according to one or more embodiments may include a cover layer arranged on the uppermost sensor insulating layer of the input sensor, and the cover layer may include an acrylate-based polymer and at least one of a silane coupling agent, an epoxy-based compound, or a polymer derived from an aromatic monomer, or the cover layer may include an epoxy acrylate-based polymer, so as to exhibit strong bonding strength with respect to the uppermost sensor insulating layer. Accordingly, the display module according to one or more embodiments and the electronic device including the display module may exhibit improved or enhanced reliability and impact resistance by maintaining excellent or suitable bonding strength between the input sensor in the display module and the cover layer even if (e.g., when) the bezel portion corresponding to the peripheral region decreases.

In one or more embodiments, the display module manufacturing method according to one or more embodiments may include providing an acrylate-based composition on an input sensor by an inkjet printing method, ultraviolet-curing the composition, and laser-cutting a display panel, an input sensor, a cover layer, and a low-reflection member in one step (e.g., act or task) after ultraviolet-curing. And the manufacturing method may be used for manufacturing a display module in which the cover layer planarizes the underlying layer while maintaining excellent or suitable bonding strength between the cover layer and underlying layer. In one or more embodiments, in the method for manufacturing a display module according to one or more embodiments, the thermal stability of the cover layer may be increased by increasing or enhancing the degree of curing of the cover layer by providing nitrogen in the step (e.g., act or task) of ultraviolet-curing to form the cover layer. Accordingly, the display module manufactured by the display module manufacturing method according to one or more embodiments and the electronic device including the display module may exhibit excellent or suitable thermal stability characteristics.

A display module of one or more embodiments and the electronic device including the display module may include a cover layer including an acrylate-based polymer and an additional compound, or including an epoxy acrylate-based compound, and may have high bonding strength with respect to a sensor insulating (e.g., electrically insulating) layer arranged directly below, whereby excellent or suitable reliability and impact resistance characteristics may be exhibited.

A display module manufacturing method of one or more embodiments may be used for manufacturing a display module having improved or enhanced impact resistance and reliability by providing an acrylate-based composition directly on a sensor insulating (e.g., electrically insulating) layer by an inkjet printing method, and forming a cover layer having excellent or suitable bonding strength with the sensor insulating layer by including the step (e.g., act or task) of ultraviolet-curing the provided acrylate-based composition.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

While the subject matter of the present disclosure has been described in connection with what is presently considered to be practical example embodiments, it is to be understood that the present disclosure is not limited to the disclosed embodiments, but in one or more embodiments, is intended to cover one or more suitable modifications and equivalent arrangements included within the spirit and scope of the appended claims and equivalents thereof. It therefore will be understood that one or more embodiments described herein are just illustrative but not limitative in all aspects.

What is claimed is:

1. A display module comprising:
a display panel comprising a display layer and an encapsulation layer on the display layer, the display layer comprising a light-emitting element;
an input sensor on the display panel and comprising a sensor conductive layer and a plurality of sensor insulating layers, the plurality of sensor insulating layers comprising an uppermost sensor insulating layer;
a cover layer directly on the uppermost sensor insulating layer of the plurality of sensor insulating layers; and
a low-reflection member on the cover layer,
wherein the cover layer comprises:
an acrylate-based polymer and at least one of a silane coupling agent, an epoxy compound, or a polymer derived from an aromatic monomer; or
an epoxy acrylate-based polymer.

2. The display module as claimed in claim 1, wherein the uppermost sensor insulating layer comprises an epoxy-based polymer.

3. The display module as claimed in claim 1, wherein:
the sensor conductive layer comprises a first sensor conductive layer and a second sensor conductive layer on the first sensor conductive layer, and
the plurality of sensor insulating layers comprises a first sensor insulating layer below the first sensor conductive layer, a second sensor insulating layer above the first sensor conductive layers, and a third sensor insulating layer that is the uppermost sensor insulating layer.

4. The display module as claimed in claim 3, wherein the first sensor insulating layer and the second sensor insulating layer each comprise at least one of silicon nitride or silicon oxynitride.

5. The display module as claimed in claim 1, wherein the cover layer comprises a cured acrylate-based composition on the input sensor, the composition being suitable for deposition by inkjet printing and curing by ultraviolet radiation.

6. The display module as claimed in claim 1, wherein the input sensor is directly on the encapsulation layer.

7. The display module as claimed in claim 1, wherein the cover layer is directly on an entire upper surface of the uppermost sensor insulating layer.

8. The display module as claimed in claim 1, wherein the low-reflection member comprises a polarizing plate and an interlayer adhesive layer directly between the cover layer and the polarizing plate.

9. The display module as claimed in claim 1,
wherein the display module is divided into an active region in which the light-emitting element is arranged and a peripheral region in which the light-emitting element is not arranged and which is on an outer side of the active region, and
wherein edge lines of the uppermost sensor insulating layer, the cover layer, and the low-reflection member overlap each other in the peripheral region.

10. A method comprising:
providing a display panel, the display panel comprising a display layer and an encapsulation layer on the display layer, the display layer comprising a light-emitting element;
forming an input sensor on the display panel, the input sensor comprising a sensor conductive layer and a plurality of sensor insulating layers;
providing an acrylate-based composition on an uppermost sensor insulating layer of the plurality of sensor insulating layers by inkjet printing;
forming a cover layer by ultraviolet-curing the acrylate-based composition;
providing a low-reflection member on the cover layer; and
laser-cutting one sides of the display panel, the input sensor, the cover layer, and the low-reflection member such that cross-sectional profiles of the display panel, the input sensor, the cover layer, and the low-reflection member are aligned,
wherein the method is a method for manufacturing a display module.

11. The method as claimed in claim 10, wherein the acrylate-based composition comprises:
an acrylate-based monomer; and at least one of a silane coupling agent, an epoxy-based monomer, or an aromatic monomer.

12. The method as claimed in claim 10, wherein the acrylate-based composition comprises an epoxy acrylate-based monomer.

13. The method as claimed in claim 10, wherein the uppermost sensor insulating layer is made from an epoxy-based compound.

14. The method as claimed in claim 10, wherein the forming of the cover layer comprises ultraviolet-curing in an N₂ atmosphere supplied with N₂ such that the O₂ content is 10% or less.

15. The method as claimed in claim 14, wherein a degree of curing of the acrylate-based composition in an entire cover layer is 95% or more.

16. An electronic device comprising:
a display module, the display module comprising a display panel and an input sensor on the display panel; and
a power module to supply power to the display module,
wherein the display module comprises:
a display panel, the display panel comprising a display layer and an encapsulation layer on the display layer, the display layer comprising a light-emitting element;
an input sensor on the display panel and comprising a sensor conductive layer and a plurality of sensor insulating layers;
a cover layer directly on an uppermost sensor insulating layer of the plurality of sensor insulating layers; and
a low-reflection member on the cover layer, and
wherein the cover layer comprises:
an acrylate-based polymer and at least one of a silane coupling agent, an epoxy-based compound, or a polymer derived from an aromatic monomer; or
an epoxy acrylate-based polymer.

17. The electronic device as claimed in claim 16, wherein the uppermost sensor insulating layer comprises an epoxy-based polymer.

18. The electronic device as claimed in claim 16, wherein:
the input sensor is directly on the encapsulation layer, and
the low-reflection member is directly on the cover layer.

19. The electronic device as claimed in claim 16, further comprising at least one of a processor or a memory.

20. The electronic device as claimed in claim 16, wherein the electronic device is an image display device, a wearable device, or a vehicle device.
